(19) United States
(12) Patent Application Publication
(10) Pub. No.: US 2024/0215303 A1
(43) Pub. Date: Jun. 27, 2024

(54) LIGHT EMITTING DEVICE, DISPLAY DEVICE, PHOTOELECTRIC CONVERSION DEVICE, AND ELECTRONIC APPARATUS

(71) Applicant: CANON KABUSHIKI KAISHA, Tokyo (JP)

(72) Inventors: SHOMA HINATA, Kanagawa (JP); TETSUO TAKAHASHI, Kanagawa (JP); YOJIRO MATSUDA, Kanagawa (JP)

(21) Appl. No.: 18/530,571

(22) Filed: Dec. 6, 2023

(30) Foreign Application Priority Data
Dec. 16, 2022 (JP) 2022-201521

(51) Int. Cl. H10K 50/858; H10K 50/856; H10K 59/35; H10K 59/65

(52) U.S. Cl. CPC H10K 50/858; H10K 50/856; H10K 59/353; H10K 59/65

(57) ABSTRACT

A light emitting device includes a substrate, a lens, and a light emitting portion arranged between a main surface of the substrate and the lens. The lens functions as a collimator. The light emitting portion includes a first reflective layer, an organic layer, and a second reflective layer from a side of the substrate in this order. The first reflective layer includes one of a convex portion and a concave portion.

### BACKGROUND OF THE INVENTION

### Field of the Invention

The present invention relates to a light emitting device, a display device, a photoelectric conversion device, and an electronic apparatus.

### Description of the Related Art

To improve light extraction efficiency in an organic light emitting display, Japanese Patent Laid-Open No. 2017-017013 describes an arrangement in which a lens is arranged on a light emitting portion and the diameter of the lens and the distance between the lens and the light emitting portion are adjusted. Japanese Patent Laid-Open No. 2019-133816 describes an arrangement in which a lower electrode layer and an organic layer are formed in a concave shape in a light emitting element including an on-chip microlens that diverges light from the organic layer.

To improve the performance of a light emitting device, it is necessary to further efficiently extract light emitted from a light emitting portion.

### SUMMARY OF THE INVENTION

The present invention provides a technique advantageous in improving light extraction efficiency.

One of aspects of the present invention provides a light emitting device comprising a substrate, a lens, and a light emitting portion arranged between a main surface of the substrate and the lens, wherein the lens functions as a collimator, the light emitting portion includes a first reflective layer, an organic layer, and a second reflective layer from a side of the substrate in this order, and the first reflective layer includes one of a convex portion and a concave portion.

Further features of the present invention will become apparent from the following description of exemplary embodiments with reference to the attached drawings.

### BRIEF DESCRIPTION OF THE DRAWINGS

FIG. 1 is a view showing an example of the arrangement of a light emitting device according to an embodiment;

FIG. 2 is a view showing an example of the arrangement of the light emitting device according to the embodiment;

FIG. 3 is a view showing an example of the arrangement of a light emitting device according to a comparative example;

FIG. 4 is a view showing an example of the arrangement of the light emitting device according to the embodiment;

FIG. 5 is a view showing an example of the arrangement of the light emitting device according to the embodiment;

FIG. 6 is a view showing an example of the arrangement of the light emitting device according to the embodiment;

FIGS. 7A to 7E are views each showing an example of the arrangement of a reflective layer of the light emitting device according to the embodiment;

FIG. 8 is a view showing an example of the arrangement of the light emitting device according to the embodiment;

FIG. 9A is a view showing an example of the arrangement of light emitting elements of the light emitting device shown in FIG. 8;

FIG. 9B is a view showing an example of the arrangement of the light emitting elements of the light emitting device shown in FIG. 8;

FIG. 9C is a view showing an example of the arrangement of the light emitting elements of the light emitting device shown in FIG. 8;

FIG. 10 is a view showing an example of the arrangement of the light emitting device according to the embodiment;

FIG. 11 is a view showing an example of the arrangement of the light emitting device according to the embodiment;

FIG. 12 is a view showing an example of the arrangement of the light emitting device according to the embodiment;

FIG. 13 is a view showing an example of a display device using the light emitting device according to the embodiment;

FIG. 14 is a view showing an example of a photoelectric conversion device using the light emitting device according to the embodiment;

FIG. 15 is a view showing an example of an electronic apparatus using the light emitting device according to the embodiment;

FIGS. 16A and 16B are views each showing an example of a display device using the light emitting device according to the embodiment;

FIG. 17 is a view showing an example of an illumination device using the light emitting device according to the embodiment;

FIG. 18 is a view showing an example of a moving body using the light emitting device according to the embodiment;

FIGS. 19A and 19B are views each showing an example of a wearable device using the light emitting device according to the embodiment; and

FIGS. 20A to 20C are views showing an image forming device according to the embodiment.

### DESCRIPTION OF THE EMBODIMENTS

Hereinafter, embodiments will be described in detail with reference to the attached drawings. Note, the following embodiments are not intended to limit the scope of the claimed invention. Multiple features are described in the embodiments, but limitation is not made to an invention that requires all such features, and multiple such features may be combined as appropriate. Furthermore, in the attached drawings, the same reference numerals are given to the same or similar configurations, and redundant description thereof is omitted.

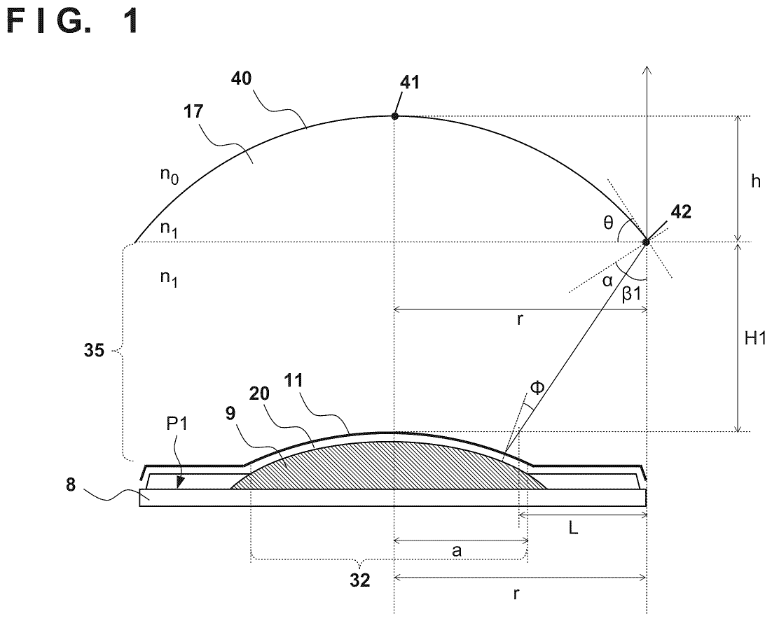

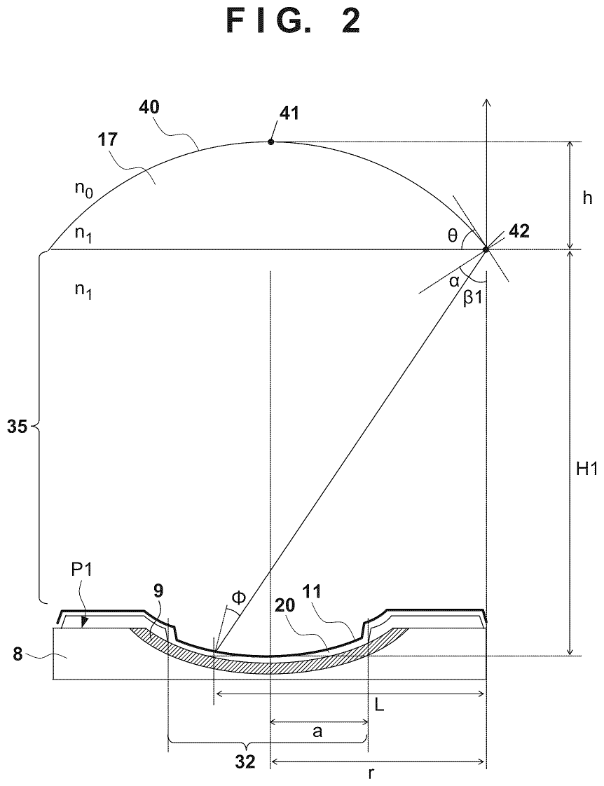

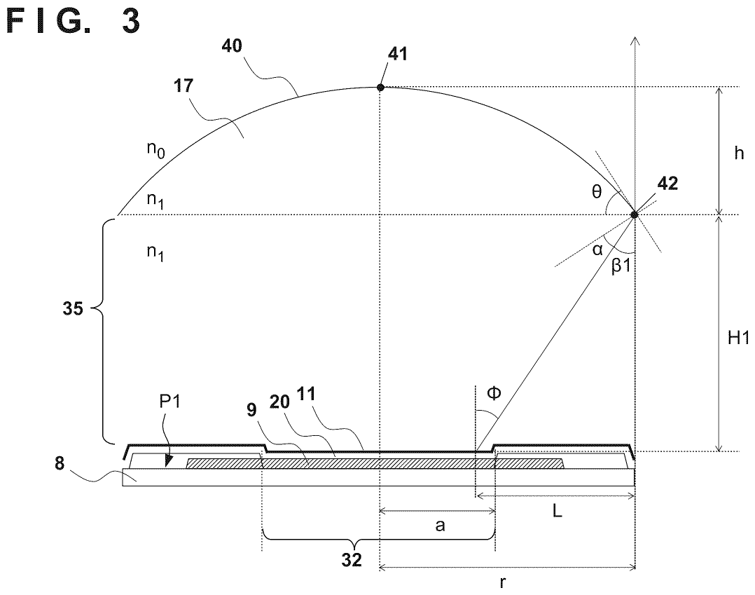

A light emitting device according to an embodiment of the present disclosure will be described with reference to FIGS. 1 to 12. FIGS. 1 and 2 are sectional views respectively showing two examples of the arrangement of a lens arranged in a light emitting device 10 according to this embodiment. FIG. 3 is a sectional view showing an example of the arrangement of a lens arranged in a light emitting device 10′ according to a comparative example. The light emitting device 10 includes a substrate 8, a lens 17 with a refractive index n arranged on a main surface of the substrate 8, and a light emitting portion 32 arranged between the lens 17 and the main surface of the substrate 8. A medium layer 35 can be arranged between the lens 17 and the light emitting portion 32. The light emitting portion 32 includes a first reflective layer 9, an organic layer 20, and a second reflective layer 11 from the side of the substrate 8 in this order. The first reflective layer 9 and the second reflective layer 11 may serve as a first electrode and a second electrode, respectively. In the example of the arrangement shown in FIG. 1, the first reflective layer 9 is formed in a concave shape. That is, in the example of the arrangement shown in FIG. 1, the first reflective layer 9 includes a convex portion or a convex surface. In the example of the arrangement shown in FIG. 2, the first reflective layer 9 is formed in a concave shape. That is, in the example of the arrangement shown in FIG. 2, the first reflective layer 9 includes a concave portion or a concave surface. The examples of the arrangement shown in FIGS. 1 and 2 can be understood as examples in which the surface (reflective surface) of the first reflective layer 9 has optical power. In the comparative example shown in FIG. 3, the first reflective layer 9 is formed in a flat plate shape parallel to the main surface of the substrate. The comparative example shown in FIG. 3 can be understood as an example in which the surface (reflective surface) of the first reflective layer 9 has no optical power. That is, the comparative example shown in FIG. 3 includes neither a convex portion nor a concave portion. In the embodiment shown in FIGS. 1 and 2 and the comparative example shown in FIG. 3, the organic layer 20 and the second reflective layer 11 are formed in conformance with the shape of the first reflective layer 9. FIGS. 1 to 3 do not illustrate components other than the above-described ones for explaining the shapes of the first reflective layer 9 and the lens 17 in detail but the detailed arrangement of the light emitting device 10 will be described later.

The central portion of the light emitting portion 32 and the central portion of the lens 17 can be arranged to overlap each other in orthogonal projection to a main surface P1 of the substrate 8. As shown in FIG. 1, the center of the light emitting portion 32 and the center of the lens 17 may be arranged to overlap each other in orthogonal projection to the main surface P1 of the substrate 8. In this case, the center of the light emitting portion 32 (lens 17) can be defined as the position of the geometric centroid of the light emitting portion 32 (lens 17) in orthogonal projection to the main surface P1 of the substrate 8. Furthermore, the central portion of the light emitting portion 32 (lens 17) can be defined as a region inside a set of positions each of which bisects a virtual line connecting the center of the light emitting portion 32 (lens 17) and the outer edge of the light emitting portion 32 (lens 17).

The lens 17 can be called a microlens or the like. The upper surface of the lens 17 has a curved surface 40 that is convex in a direction away from the main surface P1 of the substrate 8. Light obliquely emitted outward (in a direction away from the center of the light emitting portion in a planar view from a direction perpendicular to the main surface P1 of the substrate 8) from the light emitting portion 32 can be converted into parallel light (collimated light) by refraction on the curved surface 40 of the lens 17, and extracted in a front direction. That is, the lens 17 can function as a collimator. The lens 17 may have a light-harvesting property. The lens 17 can have positive power for converting light emitted from the light emitting portion 32 into parallel light or converging light.

This embodiment assumes that the curved surface 40 is part of a spherical surface. The convex curved surface 40 includes a vertex (first position) 41 and an end portion (second position) 42. The vertex 41 of the curved surface 40 is a portion, farthest from the main surface P1 of the substrate 8, of the curved surface 40 forming the upper surface of the lens 17. In the case of the arrangement shown in FIG. 1, the end portion 42 of the curved surface 40 is a portion of the lens 17 that contacts the medium layer 35. Alternatively, for example, if the outer edge portion of the lens 17 is gentle, the end portion 42 of the curved surface 40 may be a set of inflection points at which the upper surface of the lens 17 changes from the convex curved surface 40 to a concave shape. Alternatively, if the outer edge portion of the lens 17 is gentle, the end portion 42 of the curved surface 40 may be a set of points at which an angle (inclination angle θ) formed by a tangent of the curved surface 40 and the main surface P1 of the substrate 8 is largest. FIGS. 1 to 3 each show a section that passes through the vertex 41 of the curved surface 40 forming the upper surface of the lens 17 and is parallel to a normal of the main surface P1 of the substrate 8.

As shown in FIG. 1, a difference in height between the vertex 41 and the end portion 42 in the normal direction (first direction) of the main surface P1 of the substrate 8 is represented by h [μm] (to be sometimes referred to as a “distance h” hereinafter). A distance between the vertex 41 and the end portion 42 in orthogonal projection to the main surface P1 of the substrate 8 (a distance between the vertex 41 and the end portion 42 in a second direction parallel to the main surface of the substrate 8) is represented by r [μm] (to be sometimes referred to as a “distance r” hereinafter). A difference in height between the end portion 42 and the light emitting portion 32 in the normal direction of the main surface P1 of the substrate 8 is represented by H1 [μm] (to be sometimes referred to as a “distance H1” hereinafter). A distance from the center to the end portion of the light emitting portion 32 is represented by a [μm] (to be sometimes referred to as a “distance a” hereinafter).

If no lens 17 is provided, when the shape of the light emitting portion 32 is assumed to be a circular shape with the radius a, a light emission area (apparent light emission area) when observed from the normal direction (front direction) of the main surface P1 of the substrate 8 is πa². On the other hand, in the arrangements shown in FIGS. 1 and 2 in which the lens 17 is provided, the apparent light emission area viewed from the front direction is πr². The distances r and a have a relationship r>a. Therefore, if the lens 17 is provided, the apparent light emission area is increased.

Consider a path in which light emitted from the light emitting portion 32 is refracted at an interface between the lens 17 with a refractive index n1 and air with a refractive index of 1 and is extracted. In this example, assume that the refractive index of the medium layer 35 from the light emitting portion 32 to the lens 17 is also n1.

In the end portion 42 of the curved surface 40, the inclination angle θ of the lens 17 is maximum on the curved surface 40. If the curved surface 40 is a spherical surface, the inclination angle θ in the end portion 42 is obtained using the distances h and r by sine=2rh/(r²+h²). Consider a light beam that is refracted at a point with the inclination angle θ on the curved surface 40 and is extracted in the front direction (the normal direction of the main surface of the substrate 8). In this case, an incident angle α to the curved surface 40 is represented based on the Snell's law using a refractive index no of a layer (in this example, air) on the light extraction side on the curved surface 40 and the refractive index n1 of a layer (in this example of the arrangement, the lens 17) on the side of the light emitting portion 32 on the curved surface 40 by n1·sinα=n0·sinθ. Furthermore, this light beam has an angle β1 with respect to the front direction inside the layer (in this example of the arrangement, the lens 17) on the side of the light emitting portion 32 on the curved surface 40. The angle β1 is obtained by β1=|0−α|.

An emission angle φ from the light emitting portion 32 is defined, in a direction in which a positive value satisfying 0°<<<90° is obtained, as an angle formed by the light beam and the normal of the reflective surface of the first reflective layer 9. In the case of the comparative example shown in FIG. 3, since the first reflective layer 9, the organic layer 20, and the second reflective layer 11 are parallel to the main surface P1 of the substrate 8, the emission angle φ, from the light emitting portion 32, of light refracted at a point with the inclination angle θ and extracted in the front direction is equal to β1. That is, in the end portion 42 of the curved surface 40, light with the emission angle φ=β1 is extracted in the front direction.

On the other hand, in the arrangement of this embodiment, each of the first reflective layer 9, the organic layer 20, and the second reflective layer 11 includes a convex portion or a concave portion. That is, a portion inclined with respect to the main surface of the substrate is included. In this case, as shown in FIGS. 1 and 2, the emission angle φ, from the light emitting portion 32, of light refracted at a point with the inclination angle θ and extracted in the front direction is smaller than β1. That is, in the end portion 42 of the curved surface 40, light with the emission angle φ<β1 is extracted in the front direction.

If, in the light emitting portion 32 in the arrangement of this embodiment, an optical distance (to be described later) between the first reflective layer and the second reflective layer is optimized with respect to the front direction, the radiation intensity from the light emitting portion 32 may be highest in the front direction, and may become lower as the emission angle becomes larger. In this case, as compared with the example shown in FIG. 3, in the arrangements of this embodiment shown in FIGS. 1 and 2, light with the smaller emission angle φ, that is, light with relatively higher radiation intensity can be extracted in the front direction, thereby improving radiation intensity in the front direction.

Furthermore, in the organic light emitting element used for the light emitting portion 32, as a radiation angle becomes larger, the color purity of light may deteriorate. As the angle with respect to the front direction becomes larger, the deterioration of the color purity of light emitted from the light emitting portion 32 becomes larger. That is, by comparing the arrangements of this embodiment shown in FIGS. 1 and 2 with the arrangement of the comparative example shown in FIG. 3, the front extraction light amount can be increased and light with high color purity can be extracted in the arrangements of this embodiment in which light with the small emission angle φ can be extracted in the front direction.

A preferable relationship among the distances h, r, H1, and a according to this embodiment will be described. A distance by which a light beam traveling from the light emitting portion 32 to the end portion 42 of the curved surface 40 at the angle β1 travels in a direction parallel to the main surface P1 of the substrate 8 is represented by L. In the examples of the arrangement shown in FIGS. 1 and 2, it may be considered that L is almost equal to H1·tanβ1. A condition under which there exists a light beam traveling from the light emitting portion 32 to the end portion 42 of the curved surface 40 at the angle β1 is that inequality (1) below is satisfied.

$$r - a < L < r + a \qquad ( 1 )$$

That is, when inequality (1) is satisfied, there exists light that is emitted from the light emitting portion 32, refracted by the end portion 42 of the curved surface 40, and extracted in the front direction, and light extraction efficiency in the front direction is improved, as compared with a case where inequality (1) is not satisfied.

In the example shown in FIG. 1 in which the first reflective layer 9 includes the convex portion, a condition under which the emission angle q from the light emitting portion 32 is smaller than β1 is that inequality (2) below is satisfied.

$$L < r \qquad ( 2 )$$

That is, in a case where the first reflective layer 9 includes the convex portion, when inequality (2) is satisfied, it is possible to decrease the emission angle φ, as compared with a case where the first reflective layer 9 is parallel to the main surface P1 of the substrate 8, and thus light extraction efficiency in the front direction is improved and light with high color purity can be extracted, as described above. Furthermore, inequalities (1) and (2) are more preferably satisfied at the same time since light extraction efficiency in the front direction is improved. That is, in a case where the first reflective layer 9 includes the convex portion, it is more preferable to satisfy:

$$r - a < L < r \qquad ( 3 )$$

On the other hand, in the example of the arrangement shown in FIG. 2 in which the first reflective layer 9 includes the concave portion, a condition under which the emission angle φ from the light emitting portion 32 is smaller than β1 is that inequality (4) below is satisfied.

$$r < L \qquad ( 4 )$$

That is, in a case where the first reflective layer 9 includes the concave portion, when inequality (4) is satisfied, the emission angle q can be decreased, as compared with a case where the first reflective layer 9 is parallel to the main surface P1 of the substrate 8, and thus light extraction efficiency in the front direction is improved and light with high color purity can be extracted, as described above. Furthermore, inequalities (1) and (4) are more preferably satisfied at the same time since light extraction efficiency in the front direction is improved. That is, in a case where the first reflective layer 9 includes the concave portion, it is more preferable to satisfy:

$$r < L < r + a \qquad ( 5 )$$

A case where the refractive index of the medium layer 35 arranged between the light emitting portion 32 and the lens 17 is equal to the refractive index of the lens 17 has been described. A case where the refractive index of the medium layer 35 is different from that of the lens 17 and a case where the medium layer 35 is formed from a plurality of layers with different refractive indices will be described below. The medium layer 35 may be formed by stacking a plurality of layers such as a protection layer, a color filter layer, and a planarizing layer.

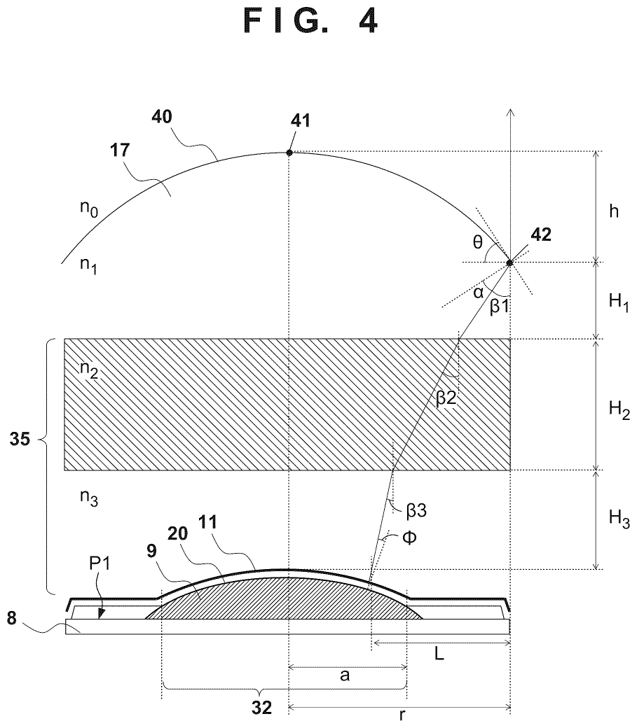

FIG. 4 is a sectional view of an example in which the medium layer 35 is formed from a plurality of layers. Even in a case where the medium layer 35 is formed from a plurality of layers with different refractive indices, when the first reflective layer 9 includes the convex portion or the concave portion, the same effect as the above-described one is obtained. That is, even in a case where the medium layer 35 is formed from a plurality of layers with different refractive indices, it is possible to decrease the emission angle φ from the light emitting portion 32, as compared with a case where the first reflective layer 9 is parallel to the main surface of the substrate, and thus light extraction efficiency in the front direction is improved and light with high color purity can be extracted. Furthermore, one of inequalities (1) to (5) is more preferably satisfied since light extraction efficiency in the front direction is improved and light with high color purity can be extracted. In this example, the distance L in each of inequalities (1) to (5) is approximately obtained by calculating the angle of the light beam in each layer in consideration of refraction at the interface of each layer. More specifically, in a case where N layers including the layer of the lens 17 are included, when the refractive index of the ith layer from the layer of the lens 17 as the first layer toward the substrate 8 is represented by ni, a light beam angle βi in the ith layer is obtained by:

$$ni \cdot sin β i = n 1 \cdot sin β 1 \qquad ( 6 )$$

A distance Li by which the light beam travels in each layer in a direction parallel to the main surface P1 of the substrate 8 is obtained using the light beam angle βi in each layer by Li=Hi·tanβi. Since the distance L is obtained by adding the distance Li in each layer from i=1 to i=N, the distance L is approximately given by:

$$L = H 1 \cdot tan β 1 + H 2 \cdot tan β 2 + … + {H}_{n} \cdot tan {β}_{N} \qquad ( 7 )$$

That is, in a case where the medium layer 35 is formed from a plurality of layers with different refractive indices, light extraction efficiency in the front direction is improved by satisfying one of inequalities (1) to (5) using L obtained by equation (7), and light with high color purity can be extracted.

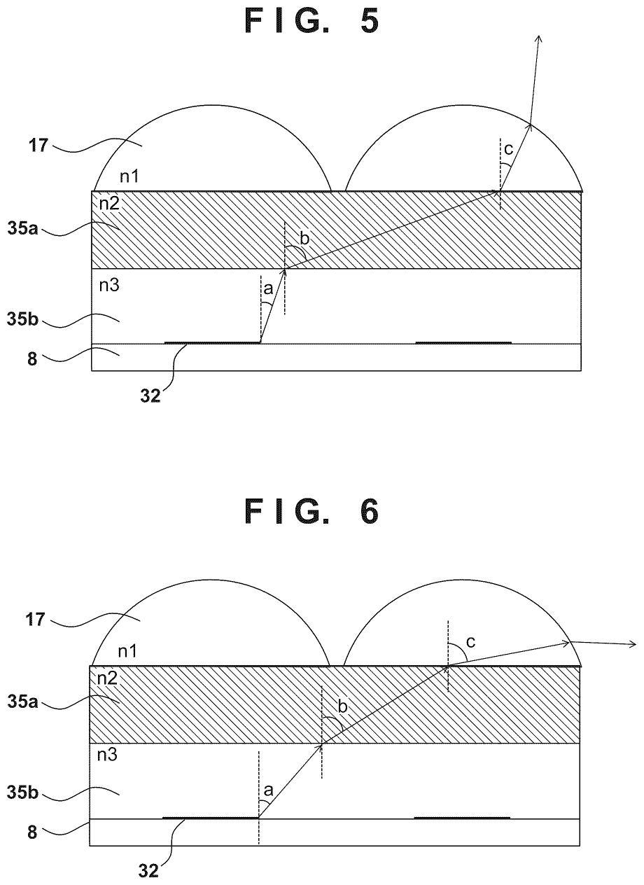

A preferable refractive index range of the medium layer in a case where a medium layer with a refractive index different from that of the lens 17 is provided between the light emitting portion 32 and the lens 17 will be described with reference to FIGS. 5 and 6. FIGS. 5 and 6 are views each showing an example of the arrangement in a case where medium layers 35a and 35b with different refractive indices are provided between the light emitting portion 32 and the lens 17. Assume that the refractive index of the medium layer 35a is n2 and the refractive index of the medium layer 35b is n3. For example, the medium layer 35a may be a color filter. Furthermore, for example, the medium layer 35b may be a protection layer.

In the arrangement shown in FIG. 5, the refractive indices have a magnitude relationship of n2<n1<n3. Considering the refraction of a light beam emitted in an oblique direction from the light emitting portion 32, angles a, b, and c have a magnitude relationship of a<c<b in accordance with the magnitude relationship among the refractive indices. When c<b, the light beam is bent in a direction close to the front direction at the interface between the medium layer 35a and the lens 17. Therefore, as shown in FIG. 5, the light emitted from the light emitting portion 32 may exit in a direction close to the front direction from the lens 17 of the adjacent light emitting element. Thus, crosstalk may occur between the light emitting elements, thereby degrading image quality. Furthermore, since the radiation angle from the light emitting portion 32 is large and light with low color purity may readily, visually be perceived, the color purity may deteriorate.

On the other hand, in the arrangement shown in FIG. 6, the refractive indices have a magnitude relationship of n1<n2<n3. Therefore, the angles a, b, and c have a magnitude relationship of a<b<c, and the light emitted in the oblique direction from the light emitting portion 32 is refracted at the interface between the medium layer 35a and the lens 17 on the wide angle side, and is difficult to exit in the front direction. Therefore, it is possible to suppress the deterioration of the color purity.

As described above, when a layer with a refractive index lower than the refractive index n1 of the lens 17 is not arranged between the light emitting portion 32 and the lens 17, it is possible to suppress crosstalk between the light emitting elements and the deterioration of the color purity. For example, in the arrangement shown in FIG. 6, the refractive index n1 of the lens 17 and the refractive index n2 of the medium layer 35a may satisfy a relationship of n1≤n2. Furthermore, the refractive index n3 of the medium layer 35b arranged between the medium layer 35a and the light emitting portion 32 may satisfy a relationship of n1≤n3. In addition, the refractive index n3 of the medium layer 35b may satisfy a relationship of n2≤n3.

A preferable range of a width a of an opening portion of the light emitting portion 32 will be described next. As described above, the effect of improvement in light extraction efficiency of the lens 17 is obtained by an increase in apparent light emission area caused by providing the lens 17. Therefore, the efficiency improvement effect is considered to be almost proportional to the ratio between the apparent light emission area and the area of the opening portion of the light emitting portion 32. That is, as a ratio r/a between the distance r in the horizontal direction from the vertex (first position) 41 to the end portion (second position) 42 of the lens 17 and the width a of the opening portion becomes higher, the efficiency improvement effect becomes larger, and power consumption reduction effect becomes larger. To produce power consumption reduction effect, r/a>1 is preferably satisfied, r/a>1.5 is more preferably satisfied, and r/a>2 is still more preferably satisfied.

On the other hand, light emitted from a region outside the opening portion of the light emitting portion 32 is refracted by the lens 17 and extracted on the wide angle side. That is, as the width a of the opening portion becomes larger, light extracted on the wide angle side increases. Therefore, as the width a of the opening portion becomes larger, the viewing angle characteristic improves. In terms of improving the viewing angle characteristic, r/a<5 is preferably satisfied and r/a<4 is more preferably satisfied.

The preferable value range of the distance h in the vertical direction and the distance r in the horizontal direction from the vertex (first position) 41 to the end portion (second position) 42 of the lens 17 will be described next. In a case where h=r, that is, h/r=1, when the curved portion of the lens 17 is a spherical surface, the inclination angle θ in the end portion 42 is 90°. A light beam that passes through the end portion 42 with 0=90° to exit in the front direction is light entering at a critical angle. In a case where one of inequalities (1) to (5) is satisfied with respect to the light beam, light that exits from a region, of the light emitting portion 32, whose distance from the center of the light emitting portion 32 becomes larger than |L−r| to reach the end portion 42 is totally reflected by the end portion 42, and is not extracted from the lens 17. Therefore, extraction efficiency is suppressed. Thus, h/r<1 is preferably satisfied since extraction efficiency is improved.

When the lens aberration becomes larger as h/r becomes higher, a light beam that is not effectively extracted may be generated, thereby degrading the light extraction efficiency. Therefore, h/r is preferably low, and h/r<0.95 is preferably satisfied and h/r<0.8 is more preferably satisfied.

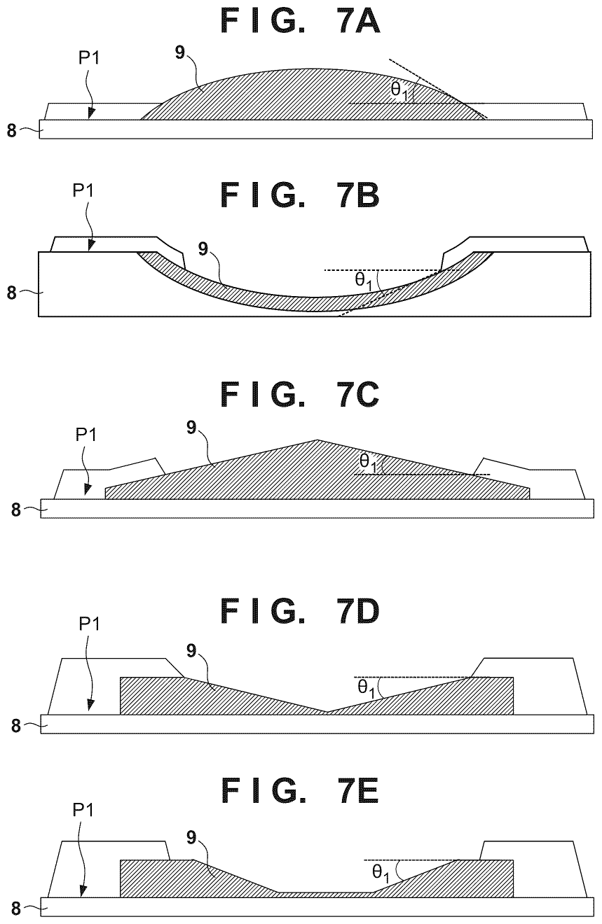

Subsequently, a preferable shape of the first reflective layer 9 will be described with reference to FIGS. 7A to 7E. FIG. 7A is a schematic view showing the first reflective layer 9 and portions associated with it in the example of the arrangement shown in FIG. 1. FIG. 7B is a schematic view showing the first reflective layer 9 and portions associated with it in the example of the arrangement shown in FIG. 2. FIGS. 7C to 7E are schematic views each showing the first reflective layer 9 and portions associated with it in another example of the arrangement of this embodiment. As described above, the first reflective layer 9 includes a convex portion or a concave portion, and the surface (reflective surface) of the first reflective layer 9 has optical power. In each of the examples shown in FIGS. 7A and 7C, a convex portion is included. In each of the examples shown in FIGS. 7B, 7D, and 7E, a concave portion is included. The convex portion or the concave portion includes, on the light extraction side, a reflective surface inclined with respect to the main surface P1 of the substrate 8. This inclination can decrease the emission angle φ from the light emitting portion, and thus light extraction efficiency in the front direction is improved and light with high color purity can be extracted, as described above. As shown in FIGS. 7A to 7E, an inclination angle θ₁ of a tangent of the reflective surface with respect to the main surface P1 of the substrate 8 is defined in a direction in which a positive value satisfying 0°<θ₁<90° is obtained.

The first reflective layer 9 includes, on the light extraction side, a reflective surface inclined with respect to the main surface P1 of the substrate 8, and the inclination angle θ₁ may continuously increase outward from the center of the first reflective layer 9, as shown in each of the examples of FIGS. 7A and 7B. As shown in each of the examples of FIGS. 7C and 7D, the inclination angle θ₁ may be constant. As shown in the example of FIG. 7E, the inclination angle θ₁ may change discontinuously.

A preferable range of the inclination angle θ₁ of the reflective surface as the surface of the first reflective layer 9 will be described below. The refractive index of a medium layer (the above-described Nth medium layer) contacting the first reflective layer 9 is represented by n_{N}. A light beam angle β_{N}, in the Nth medium layer, of light transmitted through the end portion 42 of the curved surface 40 and extracted in the front direction is obtained by n_{N}·sinβ_{N}=n1·sinβ1, as given by equation (6). In the case of the arrangement of the comparative example in which the reflective surface of the first reflective layer 9 is a flat surface (θ₁=0°) parallel to the main surface P1 of the substrate 8, the emission angle φ of the light beam from the light emitting portion 32 is given by φ=β_{N}, as described above. In the case of the arrangement of this embodiment in which θ₁>0°, the emission angle φ is given by φ=|β_{N}−θ1|. Therefore, by setting θ₁<2·β_{N}, the emission angle φ can be decreased, as compared with a case in which θ₁=0°. That is, when the shape of the reflective surface of the first reflective layer 9 is such shape that the inclination angle θ₁ at a position where light transmitted through the end portion 42 of the curved surface 40 and extracted in the front direction exits satisfies a relationship of 0<θ₁<2·β_{N}, light extraction efficiency is improved, and light with high color purity can be extracted. Furthermore, a value of |β_{N}−θ₁| is preferably closer to 0 since the improvement effect of light extraction efficiency and that of color purity are improved. To satisfy this relationship, for example, the inclination angle θ1 in a portion where the inclination angle θ1 of the reflective surface of the first reflective layer 9 is largest in the light emitting portion may satisfy 0<θ₁<2·β_{N} and, more preferably, 0.5·β_{N}<θ₁<1.5·β_{N}.

As a method of forming the convex portion or the concave portion of the first reflective layer 9, after forming a metal layer on the flat substrate 8, the shape of the convex portion or the concave portion can be formed by combining a photolithography method and an etching method. Furthermore, after forming in advance a convex portion or a concave portion on the substrate 8 using the photolithography method and the etching method, a metal layer is formed in conformance with the shape, thereby forming the convex portion or the concave portion of the first reflective layer 9. FIGS. 7A and 7C to 7E show examples of the arrangement using the flat substrate 8, and FIG. 7B shows an example of the arrangement using the substrate 8 in which the concave portion has been formed in advance.

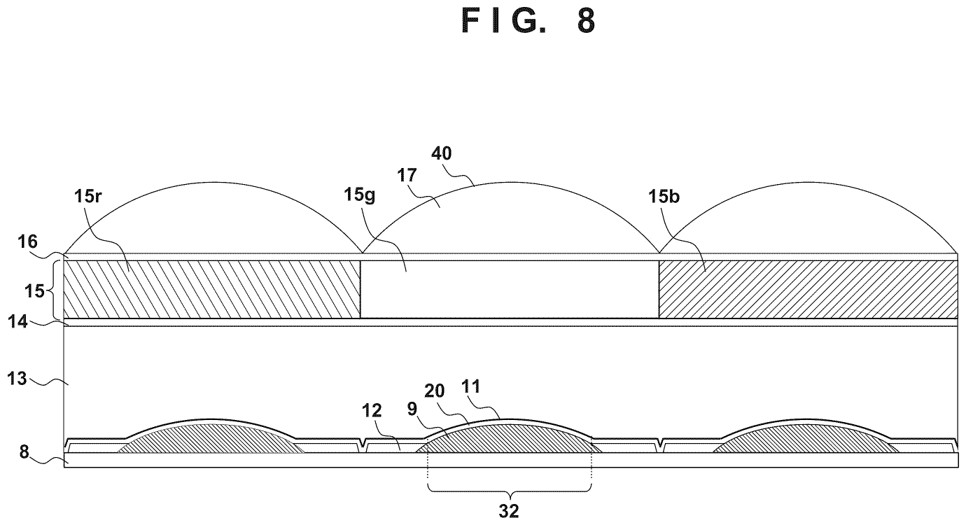

A more detailed example of the arrangement of the light emitting device 10 will be described with reference to FIG. 8. FIG. 8 is a sectional view passing through the vertex 41 of the curved surface 40 of the lens 17. As shown in FIG. 8, the light emitting device 10 can include the substrate 8, the first reflective layers (first electrodes) 9, the organic layer 20, the second reflective layer (second electrode) 11, an insulating layer 12, a protection layer 13, a planarizing layer 14, color filters 15, a planarizing layer 16, and the lenses 17. In this example of the arrangement, the first reflective layer 9 and the second reflective layer 11 function as the first electrode and the second electrode, respectively. The first reflective layers 9 as the first electrodes are arranged on the substrate 8. The first reflective layers 9 as the first electrodes can also be called lower electrodes. The organic layer 20 includes a light emitting layer containing a light emitting material. Part of the organic layer 20 (light emitting layer) functions as the above-described light emitting portion 32. The organic layer 20 is arranged between the substrate 8 and the lenses 17 to cover the first reflective layers 9 as the first electrodes. The second reflective layer 11 as the second electrode is arranged on the organic layer 20. The second reflective layer 11 as the second electrode can also be called an upper electrode. The organic layer 20 (light emitting layer) emits light by a potential difference between the first electrode (first reflective layer 9) and the second electrode (second reflective layer 11). The insulating layer 12 is arranged between the adjacent first electrodes (first reflective layers 9) so as to insulate the adjacent first electrodes (first reflective layers 9) from each other. The insulating layer 12 can also be called a bank. The insulating layer 12 is arranged in the outer edge portion on the first electrodes (first reflective layers 9). The exposed portion of each first electrode (first reflective layer 9), that is not covered with the insulating layer 12, is in contact with the organic layer 20. A portion of the organic layer 20, that is in contact with the first electrode (first reflective layer 9), can be the above-described light emitting portion 32. Therefore, as shown in FIG. 8, the plurality of light emitting portions 32 respectively corresponding to the plurality of first electrodes (first reflective layers 9) can be arranged in the light emitting device 10. The protection layer 13 is arranged on the second electrode (second reflective layer 11), and the planarizing layer 14 is arranged on the protection layer 13. The color filters 15 can be arranged on the planarizing layer 14 to respectively correspond to the plurality of light emitting portions 32. The planarizing layer 16 is arranged on the color filters 15. The lenses 17 are arranged on the planarizing layer 16. The lenses 17 are respectively arranged to correspond to the plurality of light emitting portions 32.

A material used for the substrate 8 is not particularly limited as long as the material can support the respective components of the light emitting device 10, such as the first electrodes (first reflective layers 9), the organic layer 20, and the second electrode (second reflective layer 11). For example, glass, plastic, or silicon may be used as the material of the substrate 8. A switching element such as a transistor, a wiring pattern, an interlayer insulating film, and the like may be provided in the substrate 8.

The first electrode (first reflective layer 9) may be transparent or opaque. If the first electrode (first reflective layer 9) is opaque, the material of the first electrode (first reflective layer 9) may be a metal material whose reflectance of the wavelength of light emitted from the light emitting portion 32 is 70% or more. For example, as the material of the first electrode (first reflective layer 9), a metal such as Al or Ag or an alloy obtained by adding Si, Cu, Ni, Nd, or the like to Al or Ag may be used. The first electrode may be a transparent electrode made of ITO, IZO, AZO, IGZO, or the like. In this case, the first electrode and the first reflective layer 9 can be stacked. The first electrode (first reflective layer 9) may be a stacked electrode with a barrier electrode made of a metal such as Ti, W, Mo, or Au, or an alloy thereof, or a stacked electrode with a transparent oxide film electrode made of ITO, IZO, or the like as long as a required reflectance is obtained. To optimize an optical distance (to be described later), the first reflective layer 9 as the first electrode may adopt an arrangement in which an insulating film is provided between the reflective layer and a transparent conductive film.

The second electrode (second reflective layer 11) may be a semi-transmissive electrode having a characteristic (that is, a transflective property) of transmitting part of light that has reached the second reflective layer 11 and reflecting the remaining part of the light. As the material of the second electrode (second reflective layer 11), for example, a transparent material such as a transparent conductive oxide may be used. As the material of the second electrode (second reflective layer 11), a semi-transmissive material of a single metal (Al, Ag, Au, or the like), an alkali metal (Li, Cs, or the like), an alkali earth metal (Mg, Ca, Ba, or the like), or an alloy material containing these metal materials may be used. If a semi-transmissive material is used as the material of the second electrode (second reflective layer 11), an alloy containing Mg or Ag as a main component may be used as a semi-transmissive material. The second electrode (second reflective layer 11) may have a stacked structure including a plurality of layers made of the above-described materials as long as it has an appropriate transmittance. In the arrangement shown in FIG. 8, the second electrode (second reflective layer 11) common to the plurality of light emitting portions 32 is provided. However, the present invention is not limited to this, and a plurality of second electrodes (second reflective layers 11) respectively corresponding to the plurality of light emitting portion 32 may be arranged.

One of the first electrode (first reflective layer 9) and the second electrode (second reflective layer 11) functions as an anode, and the other of the first electrode (first reflective layer 9) and the second electrode (second reflective layer 11) functions as a cathode. For example, the first electrode may function as an anode and the second electrode may function as a cathode. Alternatively, the first electrode may function as a cathode and the second electrode may function as an anode.

The organic layer 20 can be formed by a known technique such as a deposition method or a spin coating method. The organic layer 20 may be formed from a plurality of layers. If the organic layer 20 is an organic compound layer, the organic layer 20 can include at least one of a hole injection layer, a hole transport layer, an electron blocking layer, a hole blocking layer, an electron transport layer, an electron injection layer, and the like in addition to the light emitting layer.

The light emitting layer emits light when holes injected from the anode and electrons injected from the cathode are recombined in the light emitting layer. The light emitting layer may include a single layer or a plurality of layers. If, for example, a light emitting layer containing a red light emitting material, a light emitting layer containing a green light emitting material, and a light emitting layer containing a blue light emitting material are combined, light beams (red light, green light, and blue light) from the respective light emitting layers can be mixed to obtain white light. Two kinds of light emitting layers whose light emission colors have a complimentary color relationship (for example, a light emitting layer containing a blue light emitting material and a light emitting layer containing a yellow light emitting material) may be combined. In the light emitting device 10 shown in FIG. 8, each light emitting portion 32 emits white light and the light is colored in the color filter 15. However, the present invention is not limited to this. A material contained in a light emitting layer and the arrangement of the light emitting layer may be different for each light emitting portion 32 so that the light emitting layer emits light of a different color for each light emitting portion 32. In this case, the light emitting layer may be patterned for each light emitting portion 32.

The light emitting device 10 may have a so-called tandem structure in which the organic layer 20 includes a plurality of light emitting layers and a charge generating layer arranged between the plurality of light emitting layers. By having the tandem structure, the plurality of light emitting layers emit light at the same time, thereby improving light emission efficiency.

The light emitting device 10 includes the first reflective layer 9 arranged between the main surface P1 of the substrate 8 and the organic layer 20 including the light emitting layer, and the second reflective layer 11 arranged between the lens 17 and the organic layer 20 including the light emitting layer. The first reflective layer 9 may be the first electrode, or a metal layer arranged between the first electrode and the substrate 8. The second reflective layer 11 may be the second electrode, or a semi-transmissive reflective layer arranged between the second electrode and the lens 17 and having a characteristic (that is, a transflective property) of transmitting part of light that has reached the second reflective layer 11 and reflecting the remaining part of the light.

To optimize the optical distance between the first reflective surface as the upper surface of the first reflective layer 9 and the light emitting region (light emission position) of the organic layer 20 including the light emitting layer, equation (8) below is satisfied. In equation (8), Lr represents an optical path length (optical distance) from the first reflective surface as the upper surface of the first reflective layer 9 to the light emission position of the organic layer 20, Φr represents a phase shift when light of a wavelength λ is reflected by the first reflective surface, and m represents an integer of 0 or more. The film thickness between the first reflective layer 9 and the organic layer, the film thickness of each layer of the organic layer, and the like are optimized so as to satisfy equation (8).

$$Lr = ( 2 \times m - ( Φ r / π ) ) \times ( λ / 4 ) \qquad ( 8 )$$

Furthermore, if Φs represents a phase shift when light of the wavelength λ is reflected by the second reflective surface, the optical distance Ls from the light emission position to the second reflective surface as the lower surface of the second reflective layer 11 satisfies equation (9) below.

$$Ls = ( 2 \times {m}^{′} - ( Φ s / π ) ) \times ( λ / 4 ) = - ( Φ s / π ) \times ( λ / 4 ) \qquad ( 9 )$$

Therefore, a whole layer interference L satisfies equation (10) below. In equation (10), Φ represents a sum of the phase shifts Φr and Φs.

$$L = Lr + L = ( 2 \times m - Φ / π ) \times ( λ / 4 ) \qquad ( 10 )$$

In this example, in equations (8) to (10) above, an allowable range is about λ/8 or about 20 nm. Note that since it may be difficult to specify the light emission position in the organic layer 20, the interface on the first reflective surface side or the second reflective surface side of the light emitting layer is used instead of the light emission position in the above example. In consideration of the above-described allowable range, even if the interface is used instead, an effect of intensifying light can be obtained.

The protection layer 13, the planarizing layer 14, the color filters 15, and the planarizing layer 16 form the above-described medium layer 35. The protection layer 13 is a dielectric layer. The protection layer 13 is transmissive. Furthermore, the protection layer 13 may contain an inorganic material having a low permeability for oxygen and water from the outside of the light emitting device 10. For example, the protection layer 13 may be formed using an inorganic material such as silicon nitride (SiN), silicon oxynitride (SiON), silicon oxide (SiOₓ), aluminum oxide (Al₂O₃), or titanium oxide (TiO₂). In terms of the protection performance, the protection layer 13 may be made of an inorganic material such as SiN, SiON, or Al₂O₃. A chemical vapor deposition (CVD) method, an atomic deposition (ALD) method, a sputtering method, or the like can be used to form the protection layer 13.

The protection layer 13 can have a single-layer structure using the above-described material or a stacked structure using the above-described materials in combination as long as the protection layer 13 has sufficient water block performance. For example, the protection layer 13 may have a stacked structure of a layer of silicon nitride formed using the CVD method and another layer (for example, Al₂O₃) having a high density formed using the ALD method. Furthermore, the protection layer 13 may include an organic layer as long as it has water block performance. For example, polyacrylate, polyamide, polyester, epoxy, or the like can be used for the organic layer. In addition, in the arrangement shown in FIG. 8, the protection layer 13 common to the plurality of light emitting portions 32 is provided but a plurality of protection layers 13 respectively corresponding to the plurality of light emitting portions 32 may be arranged.

The lens 17 can be formed by an exposure process and a developing process. More specifically, a material film (for example, a photoresist film) of the lens 17 is formed, and the photoresist film is exposed and developed using a mask including a continuous change in gradation. As the mask used to form the lens 17, a gray mask can be used. An area gradation mask that allows light irradiation with a continuous change in gradation on the imaging plane by changing the density distribution of dots of a light shielding film with a resolution equal to or smaller than the resolution of an exposure device can be used as the mast used to form the lens 17. The lens shape can be adjusted by etching back the lens 17 formed by the exposure process and the developing process. As describe above, the upper surface of the lens 17 need only have the curved surface 40 having a light-harvesting property, and the curved surface 40 may be part of a spherical surface or an aspherical surface.

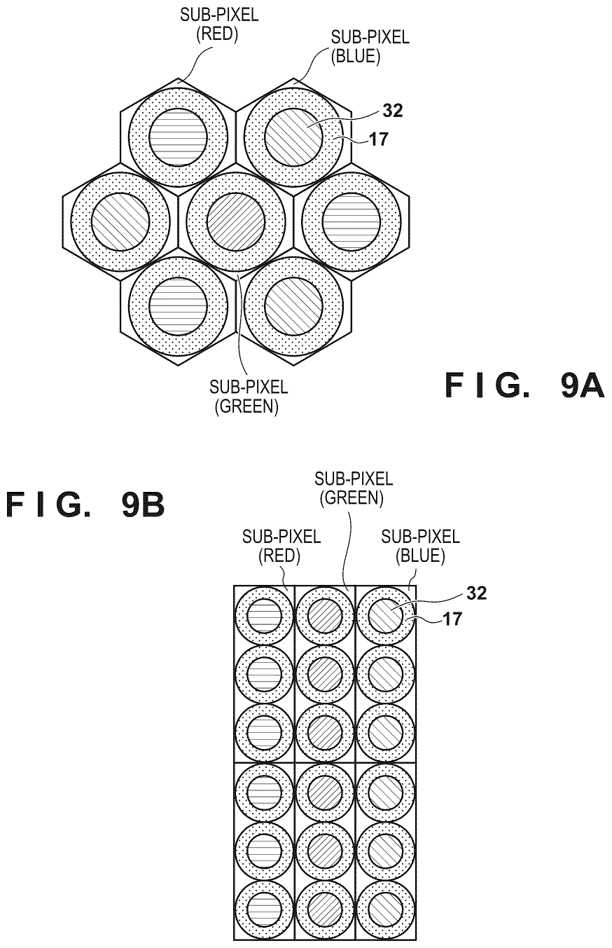

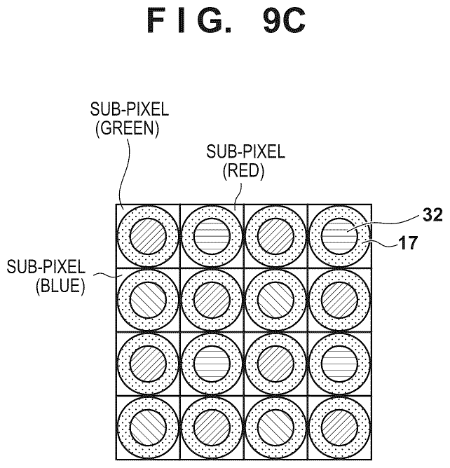

The light emitting element is formed by a combination of the light emitting portion 32, the curved surface 40 of the lens 17, and the like. If a plurality of light emitting elements are provided, the planar arrangement (the arrangement when viewed from the normal direction of the main surface of the substrate 8) of the plurality of light emitting elements may be any of a stripe arrangement, a square arrangement, a delta arrangement, a pentile arrangement, and a Bayer arrangement. FIGS. 9A to 9C are plan views when viewing the light emitting device 10 from the side of the lens 17, and each show an example of the planar arrangement of the plurality of light emitting elements. FIG. 9A shows an example of the delta arrangement. FIG. 9B shows an example of the stripe arrangement. FIG. 9C shows an example of the Bayer arrangement. In this example, consider a case where the light emitting device 10 is used as a display panel, and one pixel (main pixel) includes a plurality of sub-pixels having different corresponding color components (for example, a sub-pixel that performs red display, a sub-pixel that performs green display, and a sub-pixel that perform blue display). In this case, as shown in FIG. 9B, the plurality of light emitting elements may be arranged in one sub-pixel. The size and shape of the curved surface 40 of the lens 17 may appropriately be set in accordance with the planar arrangement of the plurality of light emitting elements. For example, if the delta arrangement is adopted, an area occupied by the curved surface 40 of the lens 17 with respect to the sub-pixel can be set large, thereby improving light extraction efficiency.

In the arrangements shown in FIGS. 9A to 9C, the planar shape of the light emitting portion 32 (the shape when viewed from the normal direction of the main surface of the substrate 8) is a circular shape but the planar shape of the light emitting portion 32 is not limited to this. The planar shape of the light emitting portion 32 may be, for example, a polygonal shape such as a rectangular or hexagonal shape. However, if the planar shape of the light emitting portion 32 is a circular shape, the relationship of the inclination angle in a direction from the end portion of the light emitting portion 32 to the end portion 42 of the curved surface 40 of the lens 17 is the same in all sections obtained by a plane in the normal direction of the main surface of the substrate 8 that passes through the vertex 41 of the curved surface 40. Therefore, it can be easy to design the light emitting device 10.

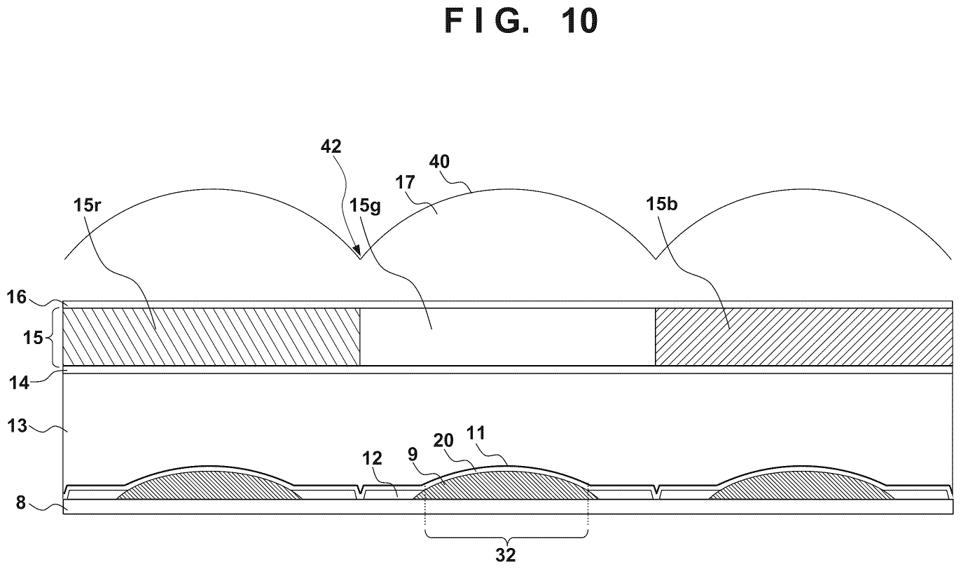

As shown in FIG. 10, the lenses 17 may be formed so that the end portion 42 of the curved surface 40 forming the upper surface of each lens 17 has a thickness (parts of the adjacent lenses 17 overlap each other). In this case, the end portion 42 of the curved surface 40 can be a set of portions (parallel to the main surface of the substrate 8) where the inclination between the adjacent lenses 17 is 0°.

As described above, an arrangement in which the lenses 17 transmit light beams of different colors may be adopted. The light emitting device 10 allows full-color display. As a method of implementing full-color display, a method of using the color filters 15 and the light emitting layer that emit white light may be adopted. Since the plurality of light emitting portions 32 can share the light emitting layer, a manufacturing process of the light emitting layer is easier than in a case where the light emitting layer is patterned to emit light of a different color for each light emitting portion 32. However, the light emitting layer may be patterned so that the plurality of light emitting portions 32 emit light beams of different colors. Furthermore, the above-described optical path length L (the optical path length Lr or Ls) between the first reflective layer and the second reflective layer may be different for each of the light emitting portions 32 that emit light beams of different colors.

As described above, the central portion of the lens 17 can be arranged to overlap the central portion of the light emitting portion 32 in orthogonal projection to the main surface of the substrate 8. As shown in FIG. 8, the center of the light emitting portion 32 and the center of the lens 17 may be arranged to overlap each other in orthogonal projection to the main surface of the substrate 8. On the other hand, to improve light extraction efficiency in a specific direction, the center of the light emitting portion 32 and the center of the lens 17 may be shifted from each other. The center of the light emitting portion 32 and the center of the lens 17 may be arranged to be shifted from each other in the same direction in the entire region of the light emitting device 10, or the center of the light emitting portion 32 and the center of the lens 17 may be arranged to overlap each other around the central portion of the light emitting device 10, and arranged to be shifted more in the outer portion of the light emitting device 10.

In this embodiment, the color filters 15 are provided on the planarizing layer 14. However, the color filters 15 may be provided on the protection layer 13. For example, the color filters 15 and the protection layer 13 may be continuous without arranging the planarizing layer 14. Alternatively, the color filters 15 and the protection layer 13 may be integrated. The color filters 15 may be formed on a support substrate different from the substrate 8 and this substrate may be bonded so as to oppose the protection layer 13, thereby forming the color filters 15 of the light emitting device 10.

The planarizing layer 14 is provided to planarize unevenness of the upper surface of the protection layer 13. By arranging the planarizing layer 14, the color filters 15 can be formed to be accurately aligned with the respective light emitting portions 32 using a photolithography process. As described above, by integrating the color filters 15 and the protection layer 13 without arranging the planarizing layer 14, the color filters 15 can be formed to be accurately aligned with the respective light emitting portions 32 using a photolithography process.

In the arrangement shown in FIG. 8, color filters 15r, 15g, and 15b may be color filters configured to transmit light beams of different colors. For example, the color filter 15r may transmit red light, the color filter 15g may transmit green light, and the color filter 15b may transmit blue light. Some or all of the plurality of color filters 15 need not be arranged. In this case, when the light emitting layer of the organic layer 20 is formed for each light emitting element, and the light emitting portions 32 emit light beams of different colors, full-color display is possible.

Furthermore, in this embodiment, the lenses 17 are provided on the planarizing layer 16. The planarizing layer 16 is provided to planarize unevenness of the upper surfaces of the color filters 15. However, the lenses 17 may be provided on the color filters 15. In this case, the planarizing layer 16 need not be arranged. Alternatively, the lenses 17 and the color filters 15 may be integrated.

Furthermore, the lenses 17 may be provided on the protection layer 13 without arranging the color filters 15 and the planarizing layers 14 and 16. For example, the lenses 17 and the protection layer 13 may be integrated. If the lenses 17 and the protection layer 13 are integrated, the distance from the lens 17 to the light emitting portion 32 can be shortened, as compared with a case where the lenses 17 are formed on another substrate and this substrate is bonded so as to oppose the protection layer 13. As a result, the solid angle of light entering the lens 17 from the light emitting portion 32 can be increased, thereby improving light extraction efficiency. By integrating the lenses 17 and the protection layer 13, the curved surface 40 of each lens 17 can be accurately aligned with the corresponding light emitting portion 32. For example, by integrating the color filters 15, the lenses 17, and the protection layer 13, the light emitting portions 32, the color filters 15, and the lenses 17 can accurately be aligned, respectively.

The stacking order of the color filters 15 and the lenses 17 can appropriately be selected. In the arrangement shown in FIG. 8, the color filters 15 are provided on the side of the light emitting portions 32 with respect to the lenses 17. In this arrangement, light emitted from the light emitting portion 32 passes through the color filter 15 before entering the lens 17. Thus, light (light having a large emission angle from the light emitting portion) that causes deterioration of the color purity passes through the color filter 15 over a relatively long distance. Therefore, it is possible to suppress the deterioration of the color purity when observing the light emitting device 10 from the oblique direction.

The light emitting device 10 may be manufactured by forming the color filters 15 and the lenses 17 on a support substrate different from the substrate 8 and bonding the substrate so as to oppose the substrate 8 including the light emitting portions 32. When the color filters 15 and the lenses 17 are formed separately from the organic layer 20 (light emitting layer), the degree of freedom of a processing method (for example, a temperature and the like) when forming the color filters 15 and the lenses 17 increases, thereby making it possible to increase the degree of freedom of the design of the color filters 15 and the lenses 17. The color filters 15 and the lenses 17 may be continuously formed on one support substrate, or the color filters 15 and the lenses 17 may be formed on different support substrates. The lenses 17 and the color filters 15 can be coupled to the substrate 8 using a coupling member such as an adhesive. The coupling member may be arranged on the planarizing layer 14, or may be arranged on the protection layer 13 in a case where the planarizing layer 14 is not arranged.

The lenses 17 may be formed on a support substrate different from the substrate 8 and the substrate may be bonded to oppose the substrate 8 including the light emitting portions 32. In this case, the lenses 17 may be fixed to the substrate 8 by a coupling member such as an adhesive in the end portion of the light emitting device 10 so as to provide a space between the lenses 17 and the protection layer 13 (or the color filters 15). In this case, the space may be filled with a resin. The refractive index of the resin may be lower than the refractive index n of the lens 17.

Examples of the light emitting device 10 will be described below.

### Example 1

First, aluminum was formed on a substrate 8 and patterned into a shape having a convex portion using a photolithography method and an etching method, thereby forming first reflective layers 9 as a plurality of first electrodes. Next, silicon oxide of a film thickness of 65 nm was formed as a material film of an insulating layer 12 to cover each of the plurality of first reflective layers 9. In the formed material film, an opening portion was formed in the central portion of each of the plurality of first reflective layers 9 to expose the first reflective layer 9, thereby forming the insulating layer 12. The shape of the opening portion that exposes the first reflective layer 9 was a circular shape having a radius of 2.0 μm. As described above, the opening portion formed in the insulating layer 12 finally corresponded to a light emitting portion 32. That is, in orthogonal projection to a main surface P1 of the substrate 8, the size and shape of the opening portion may match the size and shape of the light emitting portion 32. The inclination angle of the first reflective layer 9 in the end portion of the opening portion with respect to the main surface P1 of the substrate 8 was 30°.

After the insulating layer 12 was formed, an organic layer 20 was formed on the plurality of first reflective layers 9 and the insulating layer 12. More specifically, a hole injection layer was formed to a thickness of 3 nm by compound 1 (see the next paragraph) (the same applies to other compounds). On the hole injection layer, a hole transport layer was formed to a thickness of 15 nm by compound 2. On the hole transport layer, an electron blocking layer was formed to a thickness of 10 nm by compound 3. Next, a first light emitting layer was formed to a thickness of 10 nm such that compound 4 serving as a host material was contained in a weight ratio of 97% and compound 5 serving as a light emitting dopant was contained in a weight ratio of 3%. Next, a second light emitting layer was formed to a thickness of 10 nm such that compound 4 serving as a host material was contained in a weight ratio of 98% and compounds 6 and 7 serving as light emitting dopants were respectively contained in a weight ratio of 1%. Next, on the second light emitting layer, an electron transport layer was formed to a thickness of 110 nm by compound 8. Next, on the electron transport layer, an electron injection layer was formed to a thickness of 1 nm by lithium fluoride.

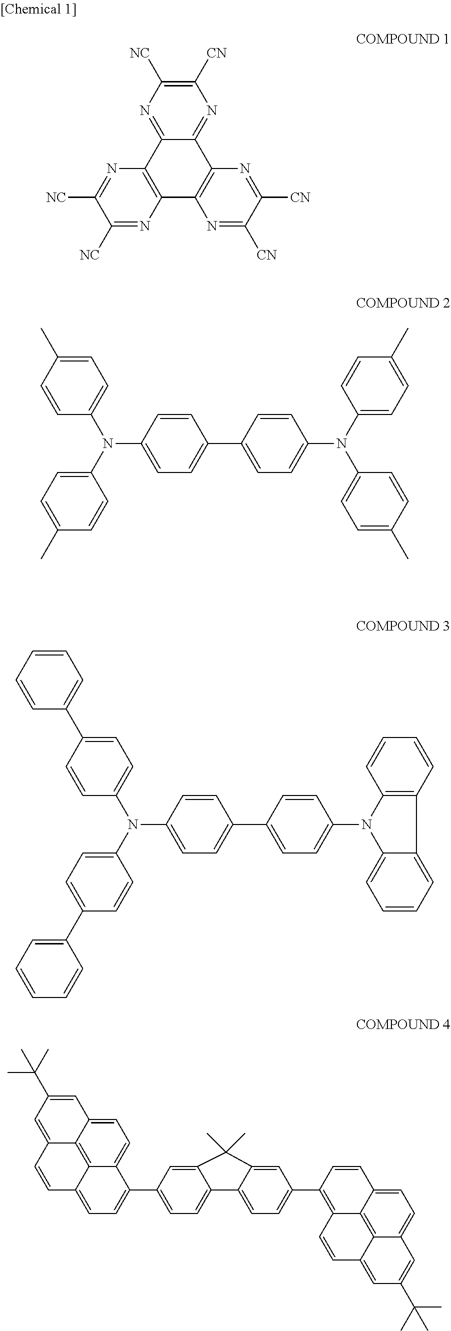

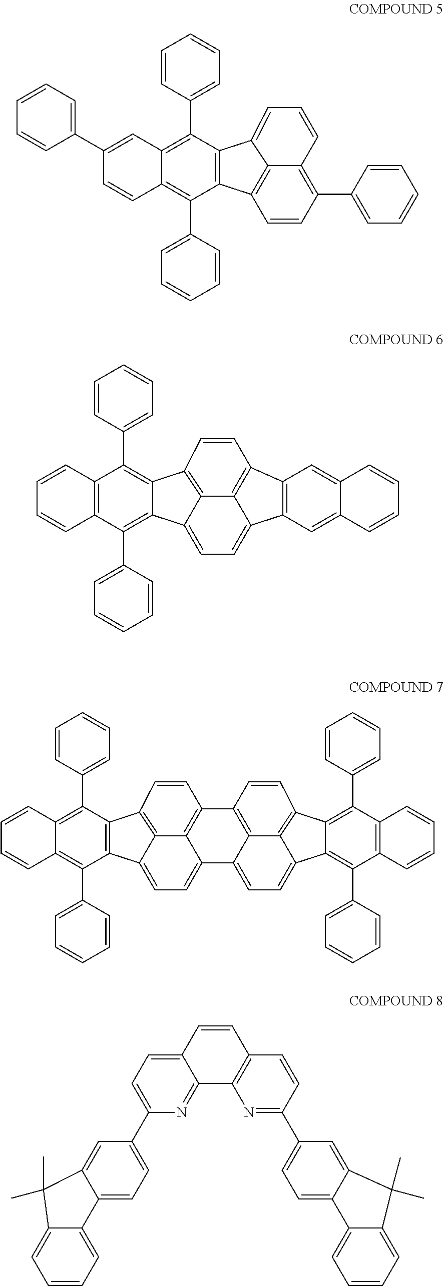

After the organic layer 20 was formed, an Mg/Ag alloy was formed to a thickness of 10 nm as a second reflective layer 11 serving as the second electrode on the organic layer 20. The ratio of Mg and Ag was 1:1. After that, as a protective layer 13, SiN with a refractive index of 1.97 was formed to a thickness of 2.0 μm on the second reflective layer 11 as the second electrode by the CVD method. Next, a planarizing layer 14 with a refractive index of 1.55 was formed to a thickness of 0.2 μm on the protection layer 13 by the spin coating method.

Next, color filters 15 with a refractive index of 1.65 were formed to a thickness of 1.6 μm on the planarizing layer 14. A color filter 15r was a color filter configured to transmit red light, a color filter 15g was a color filter configured to transmit green light, and a color filter 15b was a color filter configured to transmit blue light. After the color filters 15 were formed, a planarizing layer 16 with a refractive index of 1.55 was formed to a thickness of 0.2 μm on the color filters 15 by the spin coating method.

Next, a lens 17 with a refractive index of 1.52 was formed by an exposure process and a developing process on the planarizing layer 16. A curved surface 40 of the lens 17 was part of a spherical surface. Furthermore, a distance h as a difference in height between a vertex 41 and an end portion 42 of the curved surface 40 in the normal direction of the main surface of the substrate 8 was 2.3 μm, and a distance r between the vertex 41 and the end portion of the curved surface 40 in orthogonal projection to the main surface of the substrate 8 was 3.4 μm.

In the above-described light emitting device 10, an inclination angle θ of the end portion 42 of the lens 17 (curved surface 40) and an incident angle α of a light beam extracted in the front direction were calculated by sinθ−2rh/(r²+h²) and n1·sinα=n0·sinθ. θ=68.2° and α=37.6° were obtained. In addition, a light beam angle β1 in the lens layer was β1=θ−α=30.5°.

A light beam angle β2 in the planarizing layer 16 and a light beam angle β3 in the color filter 15, a light beam angle β4 in the planarizing layer 14, and a light beam angle β5 in the protection layer 13 were respectively calculated from the refractive indices n2 to n5 of the layers by ni·sinβi=n1·sinβ1. β2=29.9°, β3=27.9°, β4=29.9°, and β5=23.1º were obtained.

Consider a case where a light beam transmitted through the end portion 42 of the lens 17 (curved surface 40) and extracted in a direction perpendicular to the main surface P1 of the substrate 8 was tracked in a direction from the end portion 42 to the light emitting portion 32. In this case, when the light beam traveled by a distance H from the end portion 42 in a first direction as the normal direction of the main surface P1, a distance L by which the light beam traveled in a second direction as a direction parallel to the main surface P1 was calculated by L=H1·tanβ1+H2·tanβ2+ . . . +H₅·tanβ₅. In this example, since H1=0 μm, H2=0.2 μm, H3=1.6 μm, H4=0.2 μm, and H5=2.0 μm, L=1.93 μm was calculated. As described above, since r=3.4 μm and a=2.0 μm, r and a satisfied a relationship of r−a<L<r.

As a result, the manufactured light emitting device 10 was able to increase a front extraction light amount and extract light with high color purity.

### Example 2

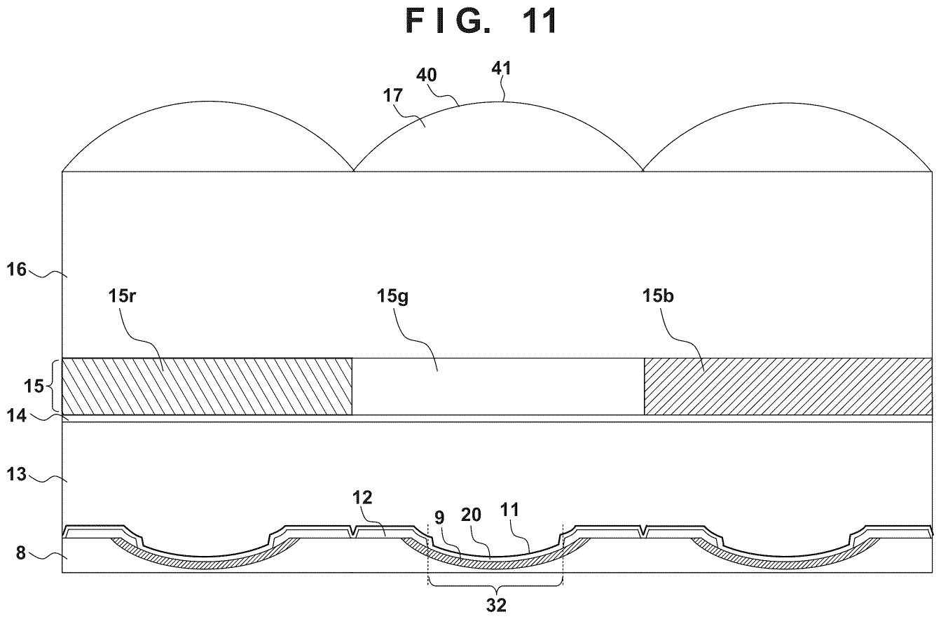

A light emitting device 10 according to Example 2 will be described next. In Example 1, the first reflective layer 9 as the first electrode included the convex portion and the planarizing layer 16 had a thickness of 0.2 μm. This example assumed that a first reflective layer 9 as a first electrode included a concave portion and a planarizing layer 16 had a thickness of 3.5 μm. The remaining components were the same as in Example 1. FIG. 11 is a sectional view showing an example of the arrangement of the light emitting device 10 according to this example and passing through a vertex 41 of a curved surface 40 of a lens 17. An inclination angle of the first reflective layer 9 as the first electrode with respect to a main surface of a substrate 8 in an end portion of an opening portion was 25°.

Since a distance h, a distance r, and a refractive index n of the lens 17 were the same as in Example 1, an inclination angle θ, an incident angle α, and an angle β1 were θ=68.2°, α=37.6°, and β1=30.5°, as in Example 1.

In a case where a light beam transmitted through the end portion 42 of the lens 17 (curved surface 40) and extracted in a direction perpendicular to the main surface of the substrate was tracked from the second position in the direction of the light emitting portion, when the light beam traveled from the second position in the first direction by a distance H, a distance L by which the light beam traveled in the second direction was calculated as 3.82 μm. As described above, since r=3.4 μm and a=2.0 μm, r and a satisfied a relationship of r<L<r+a.

As a result, the manufactured light emitting device 10 was able to increase a front extraction light amount and extract light with high color purity.

### Example 3

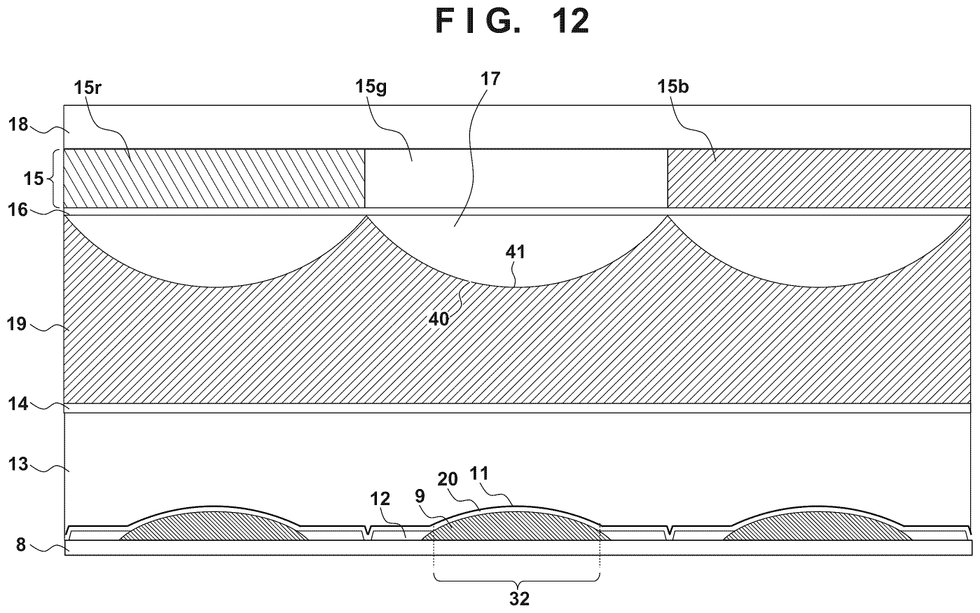

Next, a light emitting device 10 according to Example 3 will be described. In Example 3, color filters 15, a planarizing layer 16, and lenses 17 were provided on a counter substrate. FIG. 12 is a sectional view showing an example of the arrangement of the light emitting device 10 according to this example and passing through a vertex 41 of a curved surface 40 of the lens 17.

A portion from a substrate 8 to a planarizing layer 14 was manufactured, as in Example 1. Next, the color filters 15 with a refractive index of 1.65 were formed to a thickness of 1.6 μm on a substrate 18 different from the substrate 8. A color filter 15r was a color filter configured to transmit red light, a color filter 15g was a color filter configured to transmit green light, and a color filter 15b was a color filter configured to transmit blue light. After the color filters 15 were formed, the planarizing layer 16 with a refractive index of 1.55 was formed to a thickness of 0.2 μm on the color filters 15 by the spin coating method.

Next, the lens 17 with a refractive index of 1.7 was formed on the planarizing layer 16 by an exposure process and a developing process. The curved surface 40 of the lens 17 was part of a spherical surface. Furthermore, a distance h as a difference in height between the vertex 41 and an end portion 42 of the curved surface 40 in the normal direction of a main surface of the substrate 8 was 2 μm, and a distance r between the vertex 41 and the end portion of the curved surface 40 in orthogonal projection to the main surface of the substrate 8 was 3.4 μm.

Next, the lens 17 was fixed via a resin layer 19 with a refractive index of 1.52 such that the center of the lens 17 overlapped the center of the light emitting portion in a planar view. The largest thickness of the resin layer 19, that is, the distance between the end portion of the lens and the planarizing layer 14 in the normal direction of the main surface of the substrate 8 was 4.1 μm.

In the arrangement according to this example, an inclination angle θ of the end portion 42 of the lens 17 (curved surface 40) was θ=60.9° by sinθ=2rh/(r²+h²). Assume that n0 represented the refractive index of a layer (lens 17) on the light extraction side of the curved surface 40 and n1 represented the refractive index of a layer (resin layer 19) on the light emitting portion side of the curved surface 40. In this case, an incident angle α, to the curved surface 40, of a light beam extracted in the front direction and a light beam angle β1 in the resin layer 19 were α=77.8° and β1=16.9° by n1·sinα=n0·sinθ and β1=α−θ. A light beam angle β2 in a protection layer 13 was β2=13.0° by n2·sinβ2=n1·sinβ1.

A distance L was calculated by L=H1·tanβ1+H2·tanβ2. In this example, since H1=4.1 μm and H2=2.0 μm, L=1.71 μm was calculated. As described above, since r=3.4 μm and a=2.0 μm, r and a satisfied a relationship of r−a<L<r. As a result, the manufactured light emitting device 10 was able to increase a front extraction light amount and extract light with high color purity. Application examples in which the light emitting device 10 of this embodiment is applied to a display device, a photoelectric conversion device, an electronic apparatus, an illumination device, a moving body, a wearable device, and the exposure light source of an electrophotographic image forming device will be described here with reference to FIGS. 13 to 20C.

FIG. 13 is a schematic view showing an example of the display device using the light emitting device 10 of this embodiment. A display device 1000 can include a touch panel 1003, a display panel 1005, a frame 1006, a circuit board 1007, and a battery 1008 between an upper cover 1001 and a lower cover 1009. Flexible printed circuits (FPCs) 1002 and 1004 are respectively connected to the touch panel 1003 and the display panel 1005. Active elements such as transistors are arranged on the circuit board 1007. The battery 1008 is unnecessary if the display device 1000 is not a portable apparatus. Even when the display device 1000 is a portable apparatus, the battery 1008 need not be provided at this position. The light emitting device 10 can be applied to the display panel 1005. The light emitting device 10 functioning as the display panel 1005 is connected to the active elements such as transistors arranged on the circuit board 1007 and operates.

The display device 1000 shown in FIG. 13 can be used for a display unit of a photoelectric conversion device (image capturing device) including an optical unit having a plurality of lenses, and an image sensor for receiving light having passed through the optical unit and photoelectrically converting the light into an electric signal. The photoelectric conversion device can include a display unit for displaying information acquired by the image sensor. In addition, the display unit can be either a display unit exposed outside the photoelectric conversion device, or a display unit arranged in the finder. The photoelectric conversion device can be a digital camera or a digital video camera.

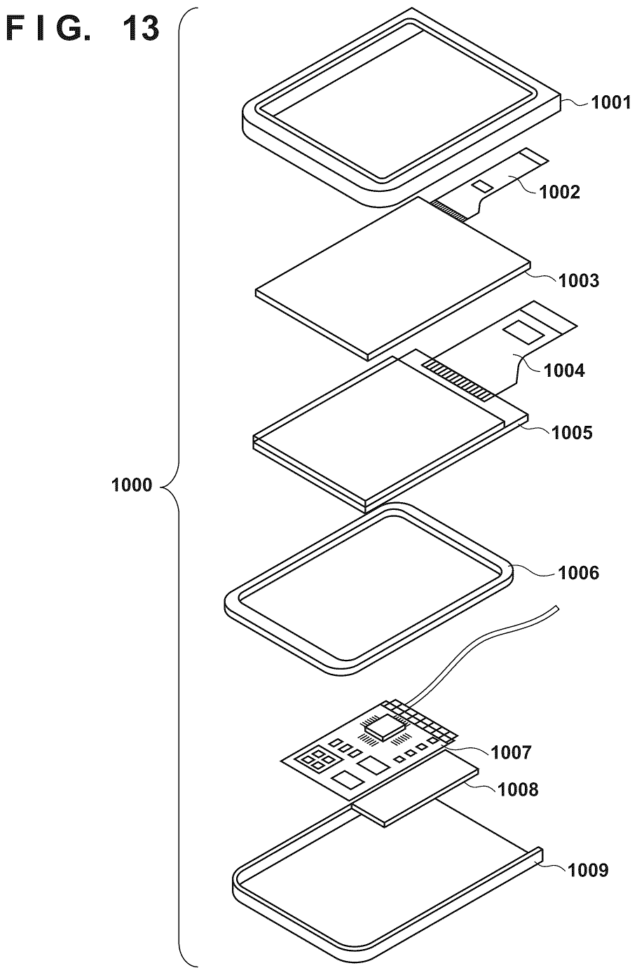

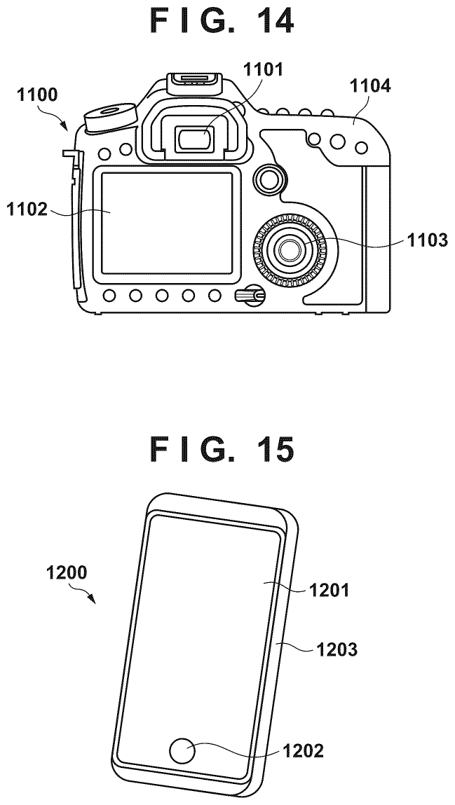

FIG. 14 is a schematic view showing an example of the photoelectric conversion device using the light emitting device 10 of this embodiment. A photoelectric conversion device 1100 can include a viewfinder 1101, a rear display 1102, an operation unit 1103, and a housing 1104. The photoelectric conversion device 1100 can also be called an image capturing device. The light emitting device 10 according to this embodiment can be applied to the viewfinder 1101 or the rear display 1102 as a display unit. In this case, the light emitting device 10 can display not only an image to be captured but also environment information, image capturing instructions, and the like. Examples of the environment information are the intensity and direction of external light, the moving velocity of an object, and the possibility that an object is covered with an obstacle.

The timing suitable for image capturing is a very short time in many cases, so the information should be displayed as soon as possible. Therefore, the light emitting device 10 in which the organic light emitting element such as an organic EL element using an organic light emitting material is arranged may be used for the viewfinder 1101 or the rear display 1102. This is so because the organic light emitting material has a high response speed. The light emitting device 10 using the organic light emitting material can be used for the apparatuses that require a high display speed more suitably than for the liquid crystal display device.

The photoelectric conversion device 1100 includes an optical unit (not shown). This optical unit has a plurality of lenses, and forms an image on a photoelectric conversion element (not shown) that receives light having passed through the optical unit and is accommodated in the housing 1104. The focal points of the plurality of lenses can be adjusted by adjusting the relative positions. This operation can also automatically be performed.

The light emitting device 10 may be applied to a display unit of an electronic apparatus. At this time, the display unit can have both a display function and an operation function. Examples of the portable terminal are a portable phone such as a smartphone, a tablet, and a head mounted display.

FIG. 15 is a schematic view showing an example of an electronic apparatus using the light emitting device 10 of this embodiment. An electronic apparatus 1200 includes a display unit 1201, an operation unit 1202, and a housing 1203. The housing 1203 can accommodate a circuit, a printed board having this circuit, a battery, and a communication unit. The operation unit 1202 can be a button or a touch-panel-type reaction unit. The operation unit 1202 can also be a biometric authentication unit that performs unlocking or the like by authenticating the fingerprint. The portable apparatus including the communication unit can also be regarded as a communication apparatus. The light emitting device 10 according to this embodiment can be applied to the display unit 1201.

FIGS. 16A and 16B are schematic views showing examples of the display device using the light emitting device 10 of this embodiment. FIG. 16A shows a display device such as a television monitor or a PC monitor. A display device 1300 includes a frame 1301 and a display unit 1302. The light emitting device 10 according to this embodiment can be applied to the display unit 1302. The display device 1300 can include a base 1303 that supports the frame 1301 and the display unit 1302. The base 1303 is not limited to the form shown in FIG. 16A. For example, the lower side of the frame 1301 may also function as the base 1303. In addition, the frame 1301 and the display unit 1302 can be bent. The radius of curvature in this case can be 5,000 mm (inclusive) to 6,000 mm (inclusive).

FIG. 16B is a schematic view showing another example of the display device using the light emitting device 10 of this embodiment. A display device 1310 shown in FIG. 16B can be folded, and is a so-called foldable display device. The display device 1310 includes a first display unit 1311, a second display unit 1312, a housing 1313, and a bending point 1314. The light emitting device 10 according to this embodiment can be applied to each of the first display unit 1311 and the second display unit 1312. The first display unit 1311 and the second display unit 1312 can also be one seamless display device. The first display unit 1311 and the second display unit 1312 can be divided by the bending point. The first display unit 1311 and the second display unit 1312 can display different images, and can also display one image together.

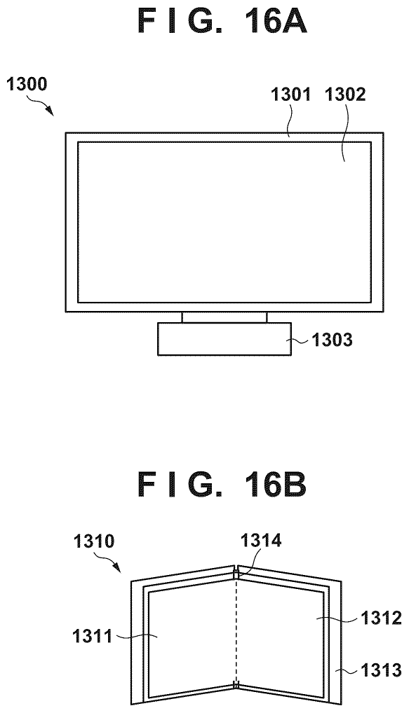

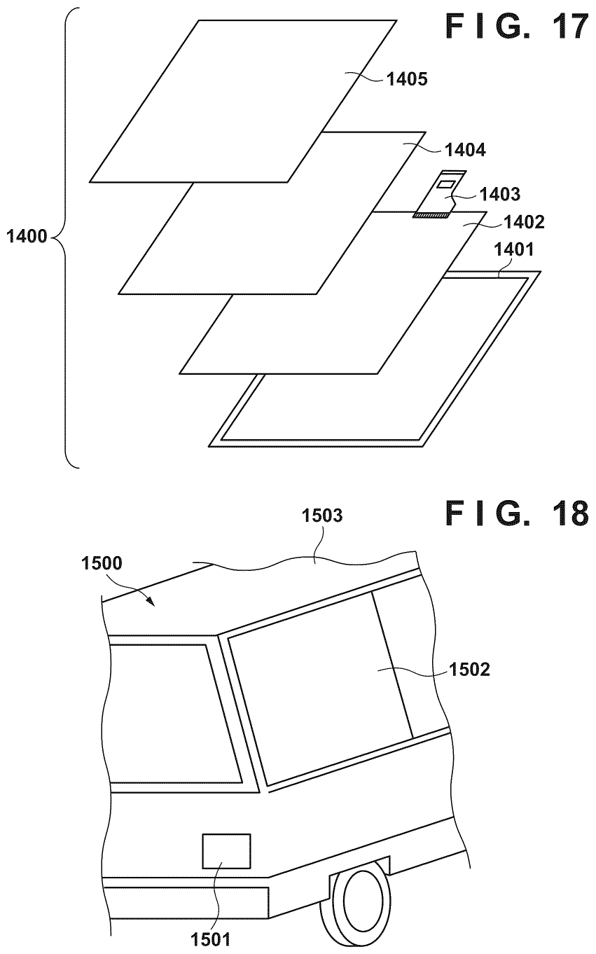

FIG. 17 is a schematic view showing an example of the illumination device using the light emitting device 10 of this embodiment. An illumination device 1400 can include a housing 1401, a light source 1402, a circuit board 1403, an optical film 1404, and a light diffusing unit 1405. The light emitting device 10 according to this embodiment can be applied to the light source 1402. The optical film 1404 can be a filter that improves the color rendering of the light source. When performing lighting-up or the like, the light diffusing unit 1405 can throw the light of the light source over a broad range by effectively diffusing the light. The illumination device can also include a cover on the outermost portion, as needed. The illumination device 1400 can include both or one of the optical film 1404 and the light diffusing unit 1405.

The illumination device 1400 is, for example, a device for illuminating the interior of the room. The illumination device 1400 can emit white light, natural white light, or light of any color from blue to red. The illumination device 1400 can also include a light control circuit for controlling these light components. The illumination device 1400 can also include a power supply circuit connected to the light emitting device 10 functioning as the light source 1402. The power supply circuit is a circuit for converting an AC voltage into a DC voltage. White has a color temperature of 4,200 K, and natural white has a color temperature of 5,000 K. The illumination device 1400 may also include a color filter. In addition, the illumination device 1400 can include a heat radiation unit. The heat radiation unit radiates the internal heat of the device to the outside of the device, and examples are a metal having a high specific heat and liquid silicon.

FIG. 18 is a schematic view of an automobile having a taillight as an example of a vehicle lighting appliance using the light emitting device 10 of this embodiment. An automobile 1500 has a taillight 1501, and can have a form in which the taillight 1501 is turned on when performing a braking operation or the like. The light emitting device 10 of this embodiment can be used as a headlight serving as a vehicle lighting appliance. The automobile is an example of a moving body, and the moving body may be a ship, a drone, an aircraft, a railroad car, an industrial robot, or the like. The moving body may include a main body and a lighting appliance provided in the main body. The lighting appliance may be used to make a notification of the current position of the main body.

The light emitting device 10 according to this embodiment can be applied to the taillight 1501. The taillight 1501 can include a protection member for protecting the light emitting device 10 functioning as the taillight 1501. The material of the protection member is not limited as long as the material is a transparent material with a strength that is high to some extent, and an example is polycarbonate. The protection member may be made of a material obtained by mixing a furandicarboxylic acid derivative, an acrylonitrile derivative, or the like in polycarbonate.

The automobile 1500 can include a vehicle body 1503, and a window 1502 attached to the vehicle body 1503. This window can be a window for checking the front and back of the automobile, and can also be a transparent display such as a head-up display. For this transparent display, the light emitting device 10 according to this embodiment may be used. In this case, the constituent materials of the electrodes and the like of the light emitting device 10 are formed by transparent members.

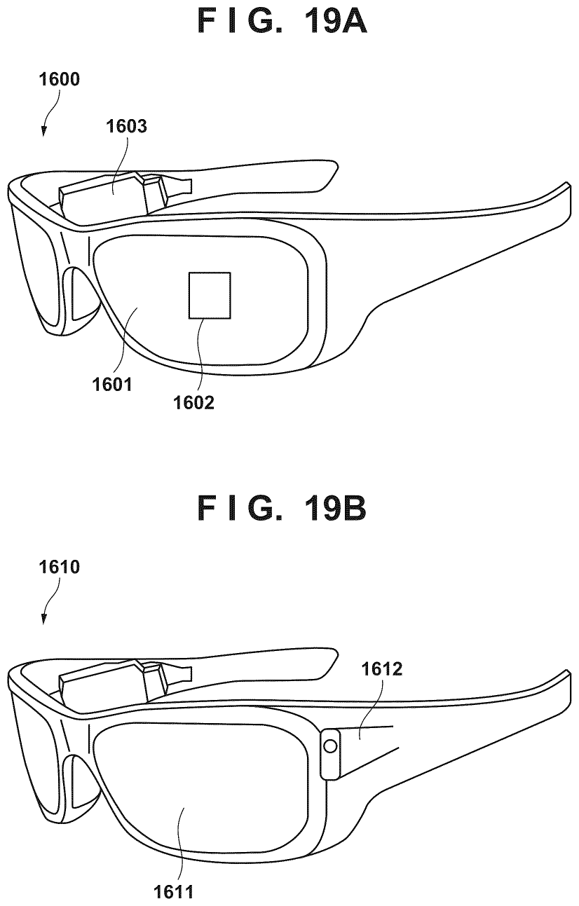

Further application examples of the light emitting device 10 according to this embodiment will be described with reference to FIGS. 19A and 19B. The light emitting device 10 can be applied to a system that can be worn as a wearable device such as smartglasses, a Head Mounted Display (HMD), or a smart contact lens. An image capturing display device used for such application examples includes an image capturing device capable of photoelectrically converting visible light and a light emitting device capable of emitting visible light.

Glasses 1600 (smartglasses) according to one application example will be described with reference to FIG. 19A. An image capturing device 1602 such as a CMOS sensor or an SPAD is provided on the surface side of a lens 1601 of the glasses 1600. In addition, the light emitting device 10 according to this embodiment is provided on the back surface side of the lens 1601.

The glasses 1600 further include a control device 1603. The control device 1603 functions as a power supply that supplies electric power to the image capturing device 1602 and the light emitting device 10 according to each embodiment. In addition, the control device 1603 controls the operations of the image capturing device 1602 and the light emitting device 10. An optical system configured to condense light to the image capturing device 1602 is formed on the lens 1601.

Glasses 1610 (smartglasses) according to one application example will be described with reference to FIG. 19B. The glasses 1610 include a control device 1612, and an image capturing device corresponding to the image capturing device 1602 and the light emitting device 10 are mounted on the control device 1612. The image capturing device in the control device 1612 and an optical system configured to project light emitted from the light emitting device 10 are formed in a lens 1611, and an image is projected to the lens 1611. The control device 1612 functions as a power supply that supplies electric power to the image capturing device and the light emitting device 10, and controls the operations of the image capturing device and the light emitting device 10. The control device 1612 may include a line-of-sight detection unit that detects the line of sight of a wearer. The detection of a line of sight may be done using infrared rays. An infrared ray emitting unit emits infrared rays to an eyeball of the user who is gazing at a displayed image. An image capturing unit including a light receiving element detects reflected light of the emitted infrared rays from the eyeball, thereby obtaining a captured image of the eyeball. A reduction unit for reducing light from the infrared ray emitting unit to the display unit in a planar view is provided, thereby reducing deterioration of image quality.

The line of sight of the user to the displayed image is detected from the captured image of the eyeball obtained by capturing the infrared rays. An arbitrary known method can be applied to the line-of-sight detection using the captured image of the eyeball. As an example, a line-of-sight detection method based on a Purkinje image obtained by reflection of irradiation light by a cornea can be used.

More specifically, line-of-sight detection processing based on pupil center corneal reflection is performed. Using pupil center corneal reflection, a line-of-sight vector representing the direction (rotation angle) of the eyeball is calculated based on the image of the pupil and the Purkinje image included in the captured image of the eyeball, thereby detecting the line-of-sight of the user.

The light emitting device 10 according to the embodiment of the present disclosure can include an image capturing device including a light receiving element, and control a displayed image based on the line-of-sight information of the user from the image capturing device.

More specifically, the light emitting device 10 decides a first visual field region at which the user is gazing and a second visual field region other than the first visual field region based on the line-of-sight information. The first visual field region and the second visual field region may be decided by the control device of the light emitting device 10, or those decided by an external control device may be received. In the display region of the light emitting device 10, the display resolution of the first visual field region may be controlled to be higher than the display resolution of the second visual field region. That is, the resolution of the second visual field region may be lower than that of the first visual field region.

In addition, the display region includes a first display region and a second display region different from the first display region, and a region of higher priority is decided from the first display region and the second display region based on line-of-sight information. The first display region and the second display region may be decided by the control device of the light emitting device 10, or those decided by an external control device may be received. The resolution of the region of higher priority may be controlled to be higher than the resolution of the region other than the region of higher priority. That is, the resolution of the region of relatively low priority may be low.

Note that AI may be used to decide the first visual field region or the region of higher priority. The AI may be a model configured to estimate the angle of the line of sight and the distance to a target ahead the line of sight from the image of the eyeball using the image of the eyeball and the direction of actual viewing of the eyeball in the image as supervised data. The AI program may be held by the light emitting device 10, the image capturing device, or an external device. If the external device holds the AI program, it is transmitted to the light emitting device 10 via communication.

When performing display control based on line-of-sight detection, smartglasses further including an image capturing device configured to capture the outside can be applied. The smartglasses can display captured outside information in real time.

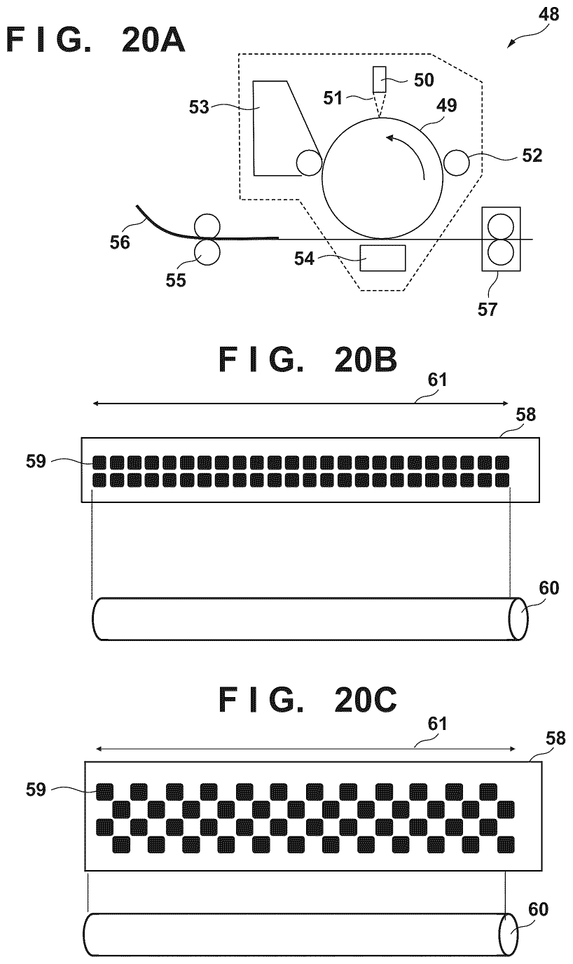

FIGS. 20A to 20C show an image forming device according to an embodiment of the present invention. FIG. 20A is a schematic view of an image forming device 48 according to the embodiment of the present invention. The image forming device includes a photosensitive member, an exposure light source, a developing unit, a charging unit, a transfer device, a conveyance roller and a fixing device.

Light 51 is emitted from an exposure light source 50, and an electrostatic latent image is formed on the surface of a photosensitive member 49. The exposure light source includes an organic light emitting element according to the present invention. A developing unit 53 includes a toner. A charging unit 52 charges the photosensitive member. A transfer device 54 transfers the developed image to a print medium 56. A conveyance unit 55 conveys the print medium 56. The print medium 56 can be, for example, paper. A fixing device 57 fixes the image formed on the print medium.

Each of FIGS. 20B and 20C is a schematic view showing a form in which a plurality of light emitting portions 59 are arranged in an exposure light source 58 on a long substrate. Reference numeral 61 denotes a direction parallel to the axis of the photosensitive member, which represents a column direction in which organic light emitting elements are arrayed. This column direction matches the direction of the axis upon rotating a photosensitive member 60. This direction can also be referred to as the long-axis direction of the photosensitive member.

FIG. 20B shows a form in which the light emitting portions are arranged along the long-axis direction of the photosensitive member. FIG. 20C shows a form which is different from that shown in FIG. 20B and in which the light emitting portions are arranged in the column direction alternately between the first column and the second column. The light emitting portions are arranged at different positions in the row direction between the first column and the second column.

In the first column, the plurality of light emitting portions are arranged apart from each other. In the second column, the light emitting portion is arranged at the position corresponding to the space between the light emitting portions in the first column. That is, in the row direction as well, the plurality of light emitting portions are arranged apart from each other.

The arrangement shown in FIG. 20C can be referred to as, for example, an arrangement in a grid pattern, an arrangement in a staggered pattern, or an arrangement in a checkered pattern.

As explained above, by using the device using the organic light emitting element according to this embodiment, stable display with good image quality can be achieved even for long periods of time.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2022-201521, filed Dec. 16, 2022, which is hereby incorporated by reference herein in its entirety.

What is claimed is:

1. A light emitting device comprising a substrate, a lens, and a light emitting portion arranged between a main surface of the substrate and the lens,
wherein the lens functions as a collimator,
the light emitting portion includes a first reflective layer, an organic layer, and a second reflective layer from a side of the substrate in this order, and
the first reflective layer includes one of a convex portion and a concave portion.

2. The device according to claim 1, wherein
in a case where
a vertex of the lens in a first direction perpendicular to the main surface of the substrate is set as a first position, and a position where an inclination angle θ of the lens is largest in a section passing through the first position and parallel to the first direction is set as a second position,
r represents a distance from the first position to the second position in a second direction parallel to the main surface of the substrate,
H represents a distance from the vertex of the first reflective layer to the second position in the first direction, and
a represents a distance from a center to an end portion of the light emitting portion in the second direction,
at a time of tracking, from the second position in a direction of the light emitting portion, a light beam transmitted through the second position and extracted in a direction perpendicular to the main surface of the substrate, letting L be a distance by which the light beam travels in the second direction while traveling from the second position in the first direction by the distance H,
a relationship of r−a<L<r+a is satisfied.

3. The device according to claim 1, wherein
the first reflective layer includes the convex portion, and
in a case where
a vertex of the lens in a first direction perpendicular to the main surface of the substrate is set as a first position, and a position where an inclination angle θ of the lens is largest in a section passing through the first position and parallel to the first direction is set as a second position,
r represents a distance from the first position to the second position in a second direction parallel to the main surface of the substrate, and
H represents a distance from the vertex of the first reflective layer to the second position in the first direction,
at a time of tracking, from the second position in a direction of the light emitting portion, a light beam transmitted through the second position and extracted in a direction perpendicular to the main surface of the substrate, letting L be a distance by which the light beam travels in the second direction while traveling from the second position in the first direction by the distance H,
a relationship of L<r is satisfied.

4. The device according to claim 2, wherein
the first reflective layer includes the convex portion, and
a relationship of r−a<L<r is satisfied.

5. The device according to claim 1, wherein
the first reflective layer includes the concave portion, and
in a case where
a vertex of the lens in a first direction perpendicular to the main surface of the substrate is set as a first position, and a position where an inclination angle θ of the lens is largest in a section passing through the first position and parallel to the first direction is set as a second position,
r represents a distance from the first position to the second position in a second direction parallel to the main surface of the substrate, and
H represents a distance from the vertex of the first reflective layer to the second position in the first direction,
at a time of tracking, from the second position in a direction of the light emitting portion, a light beam transmitted through the second position and extracted in a direction perpendicular to the main surface of the substrate, letting L be a distance by which the light beam travels in the second direction while traveling from the second position in the first direction by the distance H,
a relationship of r<L is satisfied.

6. The device according to claim 2, wherein
the first reflective layer includes the concave portion, and
a relationship of r<L<r+a is satisfied.

7. The device according to claim 1, wherein
in a case where n₁ represents a refractive index of the lens,
a medium layer with a refractive index n₂ is arranged between the light emitting portion and the lens, and
a relationship of n₁≤n₂ is satisfied.

8. The device according to claim 7, wherein the medium layer includes a color filter.

9. The device according to claim 7, wherein
the medium layer is set as a first medium layer,
a second medium layer with a refractive index n₃ is arranged between the first medium layer and the light emitting portion, and
a relationship of n₂≤n₃ is satisfied.

10. The device according to claim 1, wherein a layer with a refractive index lower than the refractive index n₁ of the lens is not arranged between the light emitting portion and the lens.

11. The device according to claim 1, wherein a central portion of the light emitting portion and a central portion of the lens are arranged to overlap each other in orthogonal projection to the main surface.

12. The device according to claim 1, wherein r>a is further satisfied.

13. The device according to claim 1, wherein the first reflective layer includes a reflective surface, and the reflective surface is part a spherical surface.

14. The device according to claim 1, wherein the first reflective layer includes a reflective surface, and the reflective surface includes a convex surface.

15. A display device comprising a light emitting device defined in claim 1, and an active element connected to the light emitting device.

16. A photoelectric conversion device comprising an optical unit including a plurality of lenses, an image sensor configured to receive light having passed through the optical unit, and a display unit configured to display an image,
wherein the display unit displays an image captured by the image sensor, and includes a light emitting device defined in claim 1.

17. An electronic apparatus comprising a housing provided with a display unit, and a communication unit provided in the housing and configured to perform external communication,
wherein the display unit includes a light emitting device defined in claim 1.

18. An image forming device comprising a photosensitive member, and an exposure light source configured to expose the photosensitive member,
wherein the exposure light source includes a light emitting device defined in claim 1.
